(19) United States
(12) Patent Application Publication
(10) Pub. No.: US 2024/0038484 A1
(43) Pub. Date: Feb. 1, 2024

(54) Fastening an object to a manipulator and/or to an object holder in a particle beam apparatus

(71) Applicant: Carl Zeiss Microscopy GmbH, Jena (DE)

(72) Inventor: Andreas Schertel, Aalen (DE)

(73) Assignee: Carl Zeiss Microscopy GmbH, Jena (DE)

(21) Appl. No.: 18/360,197

(22) Filed: Jul. 27, 2023

(30) Foreign Application Priority Data
Jul. 28, 2022 (DE) 10 2022 119 042.0

(51) Int. Cl. H01J 37/20

(52) U.S. Cl. CPC H01J 37/20; H01J 2237/2007; H01J 2237/202

(57) ABSTRACT

Fastening an object to a movable manipulator and/or an object holder in a particle beam apparatus and moving the object in the particle beam apparatus includes fastening a material unit, configured to hold an object, to the manipulator using a particle beam, fastening the object to the material unit using the particle beam, and, using the manipulator and/or an object stage, moving the object fastened to the material unit. A computer program product has program code which can be loaded into a processor and which, when executed, controls a particle beam apparatus to fasten a material unit, configured to hold an object, to the manipulator using a particle beam, fasten the object to the material unit using the particle beam, and, using the manipulator and/or an object stage, move the object fastened to the material unit.

### CROSS-REFERENCE TO RELATED APPLICATIONS

This application claims the priority of the German patent application No. 10 2022 119 042.0, filed on Jul. 28, 2022, which is incorporated herein by reference.

### TECHNICAL FIELD

This application relates to fastening an object to a movable manipulator and/or to an object holder in a particle beam apparatus and for moving the object in the particle beam apparatus.

### BACKGROUND

The practice of examining and/or analyzing objects by light microscopy has been known for a long time. In light microscopy, use is made of a light microscope which includes a beam generator for generating a light beam, an objective lens for focusing the light beam onto the object and a display device for displaying an image and/or an analysis of the object. By way of example, the display device is in the form of an eyepiece.

Further, the practice of examining objects with electron beam apparatuses has been known for a long time. For example, electron beam apparatuses, in particular a scanning electron microscope (also referred to as SEM below) and/or a transmission electron microscope (also referred to as TEM below), are used to examine objects (samples) in order to receive information about the properties and the behavior under certain conditions.

In an SEM, an electron beam (also referred to as primary electron beam below) is generated using a beam generator and focused onto an object to be examined by way of a beam guiding system. Using a deflection device in the form of a scanning device, the primary electron beam is guided in scanning fashion over a surface of the object to be examined. Here, the electrons of the primary electron beam interact with the object to be examined. As a consequence of the interaction, in particular, electrons are emitted by the object (so-called secondary electrons) and electrons of the primary electron beam are back scattered (so-called back scattered electrons). The secondary electrons and back scattered electrons are detected and used for image generation. An image representation of the object to be examined is thus obtained.

In the case of a TEM, a primary electron beam is likewise generated using a beam generator and guided using a beam guiding system onto an object to be examined. The primary electron beam passes through the object to be examined. When the primary electron beam passes through the object to be examined, the electrons of the primary electron beam interact with the material of the object to be examined. The electrons passing through the object to be examined are imaged onto a luminescent screen or onto a detector (for example a camera) by a system consisting of an objective and a projection unit. Here, imaging can also take place in the scanning mode of a TEM. Usually, such a TEM is referred to as STEM. Additionally, it may be provided that a further detector is used to detect electrons back scattered at the object to be examined and/or secondary electrons emitted by the object to be examined in order to image an object to be examined.

Furthermore, it is known from the prior art to use combination apparatuses for examining objects, where both electrons and ions can be guided onto an object to be examined. By way of example, it is known to additionally equip an SEM with an ion beam column. An ion beam generator arranged in the ion beam column is used to generate ions that are used for preparing an object (for example ablating material of the object or applying material to the object) or for imaging. For this purpose, the ions are scanned over the object using a deflection device in the form of a scanning device. The SEM serves here in particular for observing the preparation, but also for further examination of the prepared or unprepared object.

The practice of arranging an object to be examined by a particle beam apparatus on an object holder, which in turn is arranged on an object stage, is known. The object stage is arranged in a sample chamber of the particle beam apparatus. The object stage is movable, with the movable configuration of the object stage being ensured by multiple movement units, from which the object stage is assembled. The movement units enable a movement of the object stage in at least one specified direction. Object stages that have multiple translational movement units (for example approximately 3 to 4 translational movement units) and multiple rotational movement units (for example 2 to 3 rotational movement units), in particular, are known. For example, an object stage which is movable along a first translational movement axis (for example an x axis), along a second translational movement axis (for example a y axis), and along a third translational movement axis (for example a z axis) is known. The first translational movement axis, the second translational movement axis and the third translational movement axis are oriented perpendicularly to one another. Further, the known object stage is rotatable about a first axis of rotation and about a second axis of rotation, which is aligned perpendicularly to the first axis of rotation.

Gas feed devices which include one precursor reservoir or multiple precursor reservoirs, with at least one precursor being stored in each precursor reservoir are known. A precursor selected for a certain process—for example ablating material of the object or applying material to the object—is let out through an outlet of the precursor reservoir and guided to the object.

For example, the precursor is stored as a solid or liquid substance in a known precursor reservoir. In order to bring the precursor into the gaseous state, the precursor is evaporated (transition from the liquid state to the gaseous state) or sublimated (direct transition from the solid state to the gaseous state) inside the precursor reservoir. Subsequently, the precursor in the gaseous state is guided to the object for example via at least one needle-shaped capillary, such that the precursor can interact with the particle beam.

The practice of fastening an object, which is prepared from an object material, to a manipulator by deposition of a material is known. The object is connected to the manipulator in the process. The methods explained below are known from the prior art.

At a connection point between the object on the one hand and the manipulator on the other hand, material is deposited as a result of feeding a precursor and a particle beam in such a way that the object is securely connected to the manipulator. If the object is connected to the manipulator in this way, the object can be removed from the object material using the manipulator once the object has been separated from the object material, for example by using a particle beam.

As an alternative to fastening the object to the manipulator by deposition of a material, the practice of using, as manipulator, a micro-gripper having a first clamping unit and a second clamping unit is known. The object is clamped between the first clamping unit and the second clamping unit and lifted out of the object material using the micro-gripper. However, the object may be undesirably influenced, and may even be destroyed, as a result of the force exerted on the object.

The examination of a frozen object using a light microscope and/or a particle beam apparatus is known. For example, the examination of a frozen object using a light microscope and/or a particle beam apparatus is advantageous when examining biological objects. To this end, the frozen object is for example prepared from a frozen object material and arranged on a coolable object holder. For example, the object holder can be cooled to a temperature of −140° C. or less than −140° C. using liquid nitrogen or liquid helium. Temperatures below −50° C. are referred to herein as cryo-temperatures. The aforementioned object holder is arranged on an object stage of a light microscope or of a particle beam apparatus.

In order to arrange a frozen object on the object holder, it is known to initially arrange the frozen object on a manipulator and use the manipulator to move the frozen object to the object holder on which the frozen object is ultimately arranged. Usually, the manipulator is cooled in order to maintain the desired temperature.

In order to fasten the frozen object to the cooled manipulator, a precursor is guided on the one hand to the frozen object and on the other hand to the cooled manipulator via a gas feed device. On account of the low temperature, the precursor is deposited on the frozen object and on the manipulator, especially in the boundary region between the frozen object and the manipulator, and thus connects the frozen object to the manipulator. More specifically, the precursor grows on the surfaces which face the gas flow. There is no deposition, or only very little deposition, of the precursor on surfaces which face away from the gas flow. Accordingly, the frozen object is arranged on the manipulator. The above-described, known method is frequently also referred to as cold deposition. However, a disadvantage of this method is that the precursor is arranged not only in the boundary region between the frozen object and the manipulator but basically on all cold surfaces which face the gas flow, in particular on the object, the object material from which the frozen object is removed, and the manipulator. In this respect, numerous surfaces are contaminated. The contaminations make it more difficult, or even impossible, to further examine objects of the object material. In particular, the manipulator becomes contaminated in such a way that the manipulator has to be either cleaned or even fully replaced prior to being used again.

In the case of a further known method for fastening a frozen object to a cooled manipulator, a particle beam of the particle beam apparatus is used to remove ice which has vitrified on the frozen object. The removed ice is then deposited at a connection point between the object and the manipulator in such a way that the object is connected to the manipulator. However, the amount of vitrified ice that is removed by the particle beam is often not sufficient to fasten the frozen object securely to the manipulator. There is frequently an unwanted release of the frozen object from the manipulator.

It is also known to ablate material from the manipulator using a particle beam and apply the material in the boundary region between the object and the manipulator, with the result that the object is fastened to the manipulator.

With regard to the prior art, reference is made to US 2013/0001191 A1, WO 2012/138738 A2, US 2021/0225610 A1 and DE 10 2020 112 220 A1.

### SUMMARY OF THE INVENTION

It is desirable to provide a mechanism in which particular frozen objects can be properly connected to a manipulator and/or an object holder and effectively be connected in terms of time.

The method according to the system described herein serves to fasten an object to a manipulator in a particle beam apparatus and to move the object in the particle beam apparatus. For example, the particle beam apparatus is configured for analysis, observation and/or processing of the object. In particular, the particle beam apparatus includes at least one beam generator for generating a particle beam that includes charged particles. The charged particles are electrons or ions, for example. For example, the particle beam apparatus includes at least one objective lens for focusing the particle beam onto the object and/or onto a manipulator to which the object can be fastened. Further, the particle beam apparatus includes in particular at least one detector for detecting interaction particles and/or interaction radiation which arise/arises from interaction of the particle beam with the object when the particle beam is incident on the object and/or from interaction of the particle beam with the manipulator when the particle beam is incident on the manipulator. The same applies to further material units arranged on or in the particle beam apparatus.

The manipulator is for example in the form of a micro-manipulator. In particular, it is provided that the manipulator has an end region on which an object can be arranged. It is also provided that the manipulator is movable. To this end, it is provided in particular that the manipulator is connected to a movement device to be movable. For example, the movement device enables a movement of the manipulator in at least one specific direction. In particular, the movement device may have multiple translational movement units (for example 3 to 4 translational movement units) and/or multiple rotational movement units (for example 2 to 3 rotational movement units). For example, the manipulator is configured such that the manipulator is movable along a first translational movement axis (for example an x axis), along a second translational movement axis (for example a y axis), and along a third translational movement axis (for example a z axis). For example, the first translational movement axis, the second translational movement axis, and the third translational movement axis are oriented perpendicularly to one another. The manipulator may also be rotatable about a first axis of rotation and about a second axis of rotation, which is aligned perpendicularly to the first axis of rotation.

The invention is not restricted to a specific form of the manipulator. Rather, any manipulator on which the material unit can be arranged may be used in the invention. For example, the manipulator has a main body and an end, which adjoins the main body. The end is in particular pointed. In another embodiment, the manipulator has a main body and an end, which adjoins the main body and which is convex. In yet another embodiment of the manipulator, the manipulator has a main body and an end, which adjoins the main body and which is flat. In this case, for example, a first side in the form of a longitudinal side of the manipulator is ten times, fifteen times or twenty times larger than a second side in the form of a transverse side of the manipulator. In yet another embodiment of the manipulator, the manipulator has a main body and an end, which adjoins the main body and which is concave.

In the case of the method according to the system described herein, it is then provided for a material unit, configured to hold the object, to be fastened to the manipulator using a particle beam of the particle beam apparatus. Any material unit that is suitable for holding the object can be used as material unit. In this respect, the material unit is made of any desired material and/or includes the material that is suitable for holding the object. For example, the material unit is in the form of a conductive material unit and/or a metal unit. In particular, it is provided that the material unit is in the form of a material unit including copper and/or a material unit made of copper. It is explicitly pointed out that the invention is not restricted to copper as the metal. Rather, the metal unit may include any metal and/or be made from any metal that is suitable for the invention. The same also applies to alloys. The material unit may for example be generated by the method according to the system described herein. As an alternative or in addition, the material unit or the manipulator together with the material unit may be fed into the particle beam apparatus. Reference is made to the comments below, which also apply here.

For example, the material unit is fastened to the manipulator in a boundary region between the material unit and the manipulator using the particle beam of the particle beam apparatus. In particular, it is provided that the particle beam including the charged particles is guided onto the material unit and over the material unit. For example, the particle beam is scanned over the surface of the material unit using the scanning device of the particle beam apparatus. In the process, material of the material unit is ablated and reapplied in the boundary region between the material unit and the manipulator, with the result that the material unit is fastened to the manipulator. In addition or as an alternative, it is provided that the particle beam including the charged particles is guided onto the manipulator and over the manipulator. For example, the particle beam is scanned over the surface of the manipulator using the scanning device of the particle beam apparatus. In the process, material of the manipulator is ablated and reapplied in the boundary region between the manipulator and the material unit, with the result that the material unit is fastened to the manipulator.

In the case of the method according to the system described herein, it is also provided for the object to be fastened to the material unit using the particle beam of the particle beam apparatus. For example, the object is fastened to the material unit in a boundary region between the object and the material unit using the particle beam of the particle beam apparatus. In particular, it is provided that the particle beam including the charged particles is guided onto the material unit and over the material unit. For example, the particle beam is scanned over the surface of the material unit using the scanning device of the particle beam apparatus. In the process, material of the material unit is ablated and reapplied in the boundary region between the object and the material unit, with the result that the object is fastened to the material unit. In addition or as an alternative, it is provided that the particle beam including the charged particles is guided onto the object and over the object. For example, the particle beam is scanned over the surface of the object using the scanning device of the particle beam apparatus. In the process, material of the object is ablated and reapplied in the boundary region between the object and the material unit, with the result that the object is fastened to the material unit.

In the case of the system described herein, it is provided for example that the material unit is arranged between the manipulator and the object. However, the invention is not restricted to such an arrangement, as is explained in more detail below.

In the case of the method according to the system described herein, it is also provided that the object fastened to the material unit is moved using the manipulator and/or movable object stage, on which the object is arranged. For example, the object stage is arranged in a sample chamber of the particle beam apparatus. The movable configuration of the object stage is in particular ensured by a further movement device including multiple movement units from which the object stage is assembled. The movement units enable a movement of the object stage in at least one specified direction. In particular, multiple translational movement units (for example 3 to 4 translational movement units) and multiple rotational movement units (for example 2 to 3 rotational movement units) are provided. For example, the object stage is configured such that the object stage is movable along a first translational movement axis (for example an x axis), along a second translational movement axis (for example a y axis), and along a third translational movement axis (for example a z axis). For example, the first translational movement axis, the second translational movement axis, and the third translational movement axis are oriented perpendicularly to one another. The object stage is also rotatable in particular about a first axis of rotation and about a second axis of rotation, which is aligned perpendicularly to the first axis of rotation. In addition, the object stage may be moved along at least one further translational movement axis and/or rotated about at least one further axis of rotation.

For example, the object is separated from an object material before the object is moved using the manipulator. This is discussed below. Reference is made to the comments below.

The system described herein has the advantage that objects can be properly connected to a manipulator and/or an object holder and effectively be connected in terms of time. For example, the object holder is in the form of a TEM object holder. However, the invention is not restricted to such object holders. Rather, any suitable object holder may be used. The system described herein in particular makes it possible to easily introduce and arrange the object on a cooled object holder. In the case of the system described herein, an arrangement of the material unit both on the manipulator and on the object makes it possible in particular to use material of the material unit in order to fasten both the material unit to the manipulator and the object to the material unit. The material of the material unit is basically a type of adhesive, in order to fasten both the material unit to the manipulator and the object to the material unit. By contrast to the prior art, the system described herein enables a good connection both between the manipulator and the material unit and between the object and the material unit, it only being possible to inadvertently release the connection again with difficulty. The system described herein also makes it possible to provide a good connection both between the material unit and the manipulator and between the object and the material unit very quickly.

In one embodiment of the method according to the system described herein, it is additionally or alternatively provided that the material unit is generated by processing a piece of material using the particle beam of the particle beam apparatus. In this respect, it is provided in particular that the material unit is generated before and/or after the material unit is fastened to the manipulator using the particle beam of the particle beam apparatus. For example, it is provided that the material unit is cut out of the piece of material using the particle beam of the particle beam apparatus. The cutting out is effected in particular before the material unit is fastened to the manipulator. To generate the material unit, for example, the particle beam is scanned over the surface of the piece of material using the scanning device of the particle beam apparatus. In the process, material of the piece of material is ablated in such a way that the material unit is generated. The piece of material is made of any desired material and/or includes the material that is suitable for holding the object. The piece of material is in particular in the form of a conductive piece of material and/or a piece of material of metal. In particular, it is provided that the piece of material is in the form of a piece of material including copper and/or a piece of material made of copper. It is explicitly pointed out that the invention is not restricted to copper as the metal. Rather, the piece of material may include any metal and/or be made from any metal that is suitable for the invention. The same also applies to alloys. It is also pointed out that the invention is not restricted to the aforementioned embodiments for generating the material unit. Rather, the invention encompasses all methods that are suitable for generating the material unit. For example, the material unit is generated outside the particle beam apparatus using a laser device and/or saw device and/or a water jet device and/or another suitable method. After the material unit has been generated, the material unit is fed into the particle beam apparatus.

In one embodiment of the method according to the system described herein, it is additionally or alternatively provided that, before the object is fastened to the material unit, a structural unit is generated on the material unit using the particle beam of the particle beam apparatus. When the object is being fastened to the material unit, the generated structural unit is arranged on the object. The structural unit may have any form, as will be explained in more detail below.

In another embodiment of the method according to the system described herein, it is additionally or alternatively provided that, before the object is fastened to the material unit, a structural unit having at least one projection is generated on the material unit using the particle beam of the particle beam apparatus. When the object is being fastened to the material unit, the projection is arranged on the object.

In yet another embodiment of the method according to the system described herein, it is additionally or alternatively provided that, before the object is fastened to the material unit, a first structural unit is generated on the material unit using the particle beam of the particle beam apparatus. When the object is being fastened to the material unit, the generated first structural unit is arranged on a second structural unit of the object. The first structural unit and the second structural unit may have any form, as will be explained in more detail below.

In yet another embodiment of the method according to the system described herein, it is additionally or alternatively provided that, before the object is fastened to the material unit, a first structural unit having at least one first projection is generated on the material unit using the particle beam of the particle beam apparatus. When the object is being fastened to the material unit, the first projection of the first structural unit of the material unit is arranged on a first cutout of a second structural unit of the object. The first cutout may also be referred to as first recess.

In one embodiment of the method according to the system described herein, it is additionally or alternatively provided that, before the object is fastened to the material unit, firstly a first structural unit is generated on the material unit using the particle beam of the particle beam apparatus. Secondly, a second structural unit is generated on the object using the particle beam of the particle beam apparatus. When the object is being fastened to the material unit, the generated first structural unit is arranged on the generated second structural unit.

In another embodiment of the method according to the system described herein, it is additionally or alternatively provided that, before the object is fastened to the material unit, firstly a first structural unit having at least one first projection is generated on the material unit using the particle beam of the particle beam apparatus. Secondly, a second structural unit having at least one first cutout is generated on the object using the particle beam of the particle beam apparatus. When the object is being fastened to the material unit, the first projection of the first structural unit of the material unit is arranged on the first cutout of the second structural unit of the object. The first cutout may also be referred to as first recess.

As mentioned above, the aforementioned structural units may have any form. For example, the aforementioned structural units have at least one aforementioned projection. In particular, it is provided that at least one of the aforementioned structural units has a comb-like form. Such a structural unit includes multiple tines (for example in the form of projections) and cutouts, each of which is arranged between two tines.

In one embodiment of the method according to the system described herein, the comments above regarding the structural unit or the multiple structural units apply additionally or alternatively also to the fastening of the material unit to the manipulator. It is also possible to arrange at least one of the aforementioned structural units on the material unit and/or on the manipulator in order to connect the material unit to the manipulator.

It is advantageous that generating the structural unit makes it possible to enlarge the surface of the material unit on which material for connecting the material unit both to the manipulator and to the object can be deposited to ensure a particularly good connection of the material unit both to the manipulator and to the object.

As is likewise mentioned above, in yet another embodiment of the method according to the system described herein, it is additionally or alternatively provided that, to fasten the material unit to the manipulator, the particle beam of the particle beam apparatus is guided to the material unit in such a way that material of the material unit is applied both to the manipulator and to the material unit and between the manipulator and the material unit. For example, the material is applied in the boundary region between the material unit and the manipulator. In addition or as an alternative, it is provided that, to fasten the material unit to the manipulator, the particle beam of the particle beam apparatus is guided to the manipulator in such a way that material of the manipulator is applied both to the material unit and to the manipulator and between the manipulator and the material unit. For example, the material is applied in the boundary region between the material unit and the manipulator. In turn in addition or as an alternative, it is provided that, to fasten the object to the material unit, the particle beam of the particle beam apparatus is guided to the material unit in such a way that material of the material unit is applied both to the object and to the material unit and between the object and the material unit. For example, the material is applied in the boundary region between the material unit and the object. In yet another addition or as yet another alternative, it is provided that, to fasten the object to the material unit, the particle beam of the particle beam apparatus is guided to the object in such a way that material of the object is applied both to the object and to the material unit and between the object and the material unit. For example, the material is applied in the boundary region between the material unit and the object. As regards the method for applying the material, reference is made to the comments above, which also apply to all the aforementioned embodiments.

In yet another embodiment of the method according to the system described herein, it is additionally or alternatively provided that the material unit used has a first side, on which the material unit is fastened to the manipulator. The material unit also has a second side, on which the object is fastened to the material unit. For example, the first side and the second side of the material unit are aligned in relation to one another such that the material unit is arranged between the manipulator and the object. In particular, it is provided that the first side and the second side are situated opposite one another. It is explicitly pointed out that the invention is not restricted to the aforementioned alignment of the first side and the second side. Rather, any alignment that is suitable for the invention can be used. For example, the first side and the second side may be aligned at an angle in relation to one another which is not 0° or 180°. All of the embodiments mentioned here regarding the alignment of the first side in relation to the second side of the material unit have the advantages explained above.

In one embodiment of the method according to the system described herein, it is additionally or alternatively provided that the object is removed from an object material when the object is being moved using the manipulator and/or the object stage. The object material is the material from which the object that is to be analyzed, processed and/or imaged is prepared. The object is prepared for example using the particle beam of the particle beam apparatus and includes in particular separating the object from the object material. In this respect, it is provided for example that the object is separated from the object material before the object is moved using the manipulator and/or the object stage. If the object is moved exclusively using the manipulator, it is provided for example that the object is completely separated from the object material.

In another embodiment of the method according to the system described herein, it is additionally or alternatively provided that, when the object is being moved using the manipulator, the manipulator is moved by a first movement device. In addition or as an alternative, when the object is being moved using the object stage, the object stage is moved using a second movement device. The first movement device for the manipulator is for example in the form of the movement device explained above regarding the manipulator. Reference is made to the comments above, which also apply here. The second movement device for the object stage includes for example the movement device explained above regarding the object stage. Reference is made to the comments above, which also apply here.

In another embodiment of the method according to the system described herein, it is additionally or alternatively provided that, after the object has been moved using the manipulator and/or the object stage, the object is fastened to an object holder using the particle beam of the particle beam apparatus. For example, the object holder is in the form of a TEM object holder. However, the invention is not restricted to such object holders. Rather, any suitable object holder may be used. In particular, a cooled object holder is used.

To fasten the object to the object holder, it is provided for example that the particle beam including the charged particles is guided onto the object and over the object. For example, the particle beam is scanned over the surface of the object using the scanning device of the particle beam apparatus. In the process, material of the object is ablated and reapplied in the boundary region between the object and the object holder, with the result that the object is fastened to the object holder. In addition or as an alternative, it is provided that the particle beam including the charged particles is guided onto the object holder and over the object holder. For example, the particle beam is scanned over the surface of the object holder using the scanning device of the particle beam apparatus. In the process, material of the object holder is ablated and reapplied in the boundary region between the object and the object holder, with the result that the object is fastened to the object holder.

In yet another embodiment of the method according to the system described herein, it is additionally or alternatively provided that, after the object has been moved using the manipulator and/or the object stage, the object is released from the material unit using the particle beam of the particle beam apparatus. For example, releasing the object using the particle beam of the particle beam apparatus is effected after the object has been fastened to the aforementioned object holder. To release the object from the material unit, it is provided for example that the particle beam including the charged particles is guided onto the object and over the object. For example, the particle beam is scanned over the surface of the object using the scanning device of the particle beam apparatus. In the process, material is ablated in the boundary region between the object and the material unit, with the result that the object is released from the material unit. In addition or as an alternative, it is provided that a part of the material unit is separated from the material unit using the particle beam of the particle beam apparatus. However, the severed part of the material unit remains fixedly connected to the object. The material unit, which is no longer connected to the object, can be reused, for example for the method according to the system described herein. In turn in addition or as an alternative, it is provided that a part of the object is separated from the rest of the object using the particle beam of the particle beam apparatus. However, the severed part of the object remains fixedly connected to the material unit. The rest of the object remains, for example, on the object holder and is imaged, analyzed and/or processed.

As explained above, the material unit is made of any desired material and/or includes the material that is suitable for holding the object. As mentioned above, in yet another embodiment of the method according to the system described herein, it is additionally or alternatively provided that a conductive material unit and/or a metal unit is used as the material unit. In particular, it is provided that the material unit used is a material unit including copper and/or a material unit made of copper. It has been shown that copper exhibits a particularly good material redeposition rate. Expressed differently, in the event of the ablation of material of a material unit made of copper or one including copper, it is especially the case that enough material is ablated for it to be possible to achieve a secure connection of the material unit both to the manipulator and to the object owing to the amount of material that is deposited. It is explicitly pointed out that the invention is not restricted to copper as the metal. Rather, the metal unit may include any metal and/or be made from any metal that is suitable for the invention. The same also applies to alloys.

In one embodiment of the method according to the system described herein, it is additionally or alternatively provided that the material unit is fastened to the manipulator using a first gas, which is provided by a first gas feed device. For example, the material unit is fastened to the manipulator by cold deposition. As explained above, the material unit can be fastened to the manipulator additionally or alternatively also by ablating and reapplying material. For example, to this end, the first gas feed device, which includes one precursor reservoir or multiple precursor reservoirs, with at least one precursor being stored in each precursor reservoir, is used to let out a precursor from an outlet of the precursor reservoir and guide the precursor to the material unit. As a result of interaction of the precursor with the particle beam, material of the material unit is ablated and/or material is applied to the material unit and/or the manipulator.

In another embodiment of the method according to the system described herein, it is additionally or alternatively provided that the object is fastened to the material unit using a second gas, which is provided by a second gas feed device. For example, the object is fastened to the material unit by cold deposition. As explained above, the object can be fastened to the material unit additionally or alternatively also by ablating and reapplying material. For example, to this end, the second gas feed device, which includes one precursor reservoir or multiple precursor reservoirs, with at least one precursor being stored in each precursor reservoir, is used to let out a precursor from an outlet of the precursor reservoir and guide the precursor to the material unit. As a result of interaction of the precursor with the particle beam, material of the material unit is ablated and/or material is applied to the material unit and/or the object.

In yet another embodiment of the method according to the system described herein, it is additionally or alternatively provided that an identical and/or single gas feed device is used as the first gas feed device and the second gas feed device.

In another embodiment of the method according to the system described herein, additionally or alternatively, the object is fastened to the aforementioned object holder and/or the object is released from the material unit using at least one of the aforementioned gas feed devices. Reference is made to the comments above, which also apply here.

In yet another embodiment of the method according to the system described herein, it is additionally or alternatively provided that the material unit is generated using the particle beam of the particle beam apparatus in such a way that the material unit includes a first material part and a second material part, with the first material part being arranged on the second material part. Expressed differently, the material unit has a multi-part form, with the material unit including at least the first material part and at least the second material part. Accordingly, the material unit may also have more than two material parts. For example, the material unit is generated in such a way that the first material part is aligned in relation to the second material part in such a way that the angle between the first material part and the second material part is not 0° or 180°. In particular, it is provided that the angle between the first material part and the second material part is 90° or substantially 90°. It is pointed out that the invention is not restricted to the aforementioned angles. Rather, any angle that is suitable for the invention can be used. With regard to the multi-part form of the material unit, reference is also made to the comments above, which also apply here. Regarding the formation of the first material part and/or the second material part, reference is also made to the comments above and below relating to the formation of the material unit, which also apply here.

In yet another embodiment of the method according to the system described herein, it is additionally or alternatively provided that the manipulator and/or the object and/or the material unit are/is cooled. To this end, the manipulator is arranged for example on a first heating and/or cooling device. For example, the object is arranged on a second heating and/or cooling device. The material unit is also arranged in particular on a third heating and/or cooling device. At least two of the aforementioned heating and/or cooling devices have identical designs and/or are formed by a single heating and/or cooling device. In particular, the manipulator and/or the object and/or the material unit are/is cooled to a temperature of −140° C. or less than −140° C. using liquid nitrogen or liquid helium. Temperatures below −50° C. are referred to herein as cryo-temperatures.

The system described herein also relates to a computer program product having program code, which can be loaded or is loaded into a processor and which, when executed, controls a particle beam apparatus in such a way that the method according to the system described herein having one of the features mentioned herein or having a combination of at least two of the features mentioned herein is carried out.

The system described herein further relates to a particle beam apparatus for the analysis, imaging and/or processing of an object. The particle beam apparatus according to the system described herein is configured to carry out a method having at least one of the features described herein or having a combination of at least two of the features described herein.

The particle beam apparatus according to the system described herein includes at least one movable manipulator and at least one movable object stage for arranging the object. With regard to the movable manipulator and the movable object stage, reference is made to the comments above, which also apply here. The particle beam apparatus according to the system described herein also includes at least one material unit, which can be fastened to the manipulator. Moreover, the particle beam apparatus according to the system described herein includes at least one beam generator for generating a particle beam includes charged particles. The charged particles are electrons or ions, for example. The particle beam apparatus according to the system described herein is also provided with at least one objective lens for focusing the particle beam onto the object and/or onto the material unit and/or onto the manipulator. The particle beam apparatus according to the system described herein also includes at least one scanning device for scanning the particle beam over the object and/or over the material unit and/or over the manipulator. In addition, the particle beam apparatus includes at least one detector unit for detection of interaction particles and/or interaction radiation which result/results from interaction of the particle beam with the object when the particle beam is incident on the object and/or from interaction of the particle beam with the manipulator when the particle beam is incident on the manipulator and/or from interaction of the particle beam with the material unit when the particle beam is incident on the material unit. The particle beam apparatus according to the system described herein includes a processor in which a computer program product having at least one of the features described herein or having a combination of at least two of the features described herein is loaded.

In one embodiment of the particle beam apparatus according to the system described herein, it is additionally or alternatively provided that the material unit has a structural unit, which can be arranged on the object. In addition or as an alternative, it is provided that the material unit has a structural unit with at least one projection, the projection being able to be arranged on the object. In turn in addition or as an alternative, it is provided that the material unit has a first structural unit, with the object having a second structural unit and the first structural unit being able to be arranged on the second structural unit. In another embodiment, it is additionally or alternatively provided that the material unit has a first structural unit with at least one first projection, with the object having a second structural unit with at least one first cutout and the first projection being able to be arranged on the first cutout. As mentioned above, the aforementioned structural units may have any form. For example, the aforementioned structural units have at least one aforementioned projection. In particular, it is provided that at least one of the aforementioned structural units has a comb-like form. Such a structural unit includes multiple tines (for example in the form of projections) and cutouts, each of which is arranged between two tines.

In one embodiment of the particle beam apparatus according to the system described herein, the comments above regarding the structural unit or the multiple structural units apply additionally or alternatively also to the fastening of the material unit to the manipulator. It is also possible to arrange at least one of the aforementioned structural units on the material unit and/or on the manipulator in order to connect the material unit to the manipulator.

It is advantageous that the structural unit makes it possible to enlarge the surface of the material unit on which material for connecting the material unit both to the manipulator and to the object can be deposited to ensure a particularly good connection of the material unit both to the manipulator and to the object.

In another embodiment of the particle beam apparatus according to the system described herein, it is additionally or alternatively provided that the material unit has a first side for fastening to the manipulator and a second side for fastening the object. For example, the first side and the second side of the material unit are aligned in relation to one another such that the material unit is arranged between the manipulator and the object. In particular, it is provided that the first side and the second side are situated opposite one another. It is explicitly pointed out that the invention is not restricted to the aforementioned alignment of the first side and the second side. Rather, any alignment that is suitable for the invention can be used. For example, the first side and the second side may be aligned at an angle in relation to one another which is not 0° or 180°. All of the embodiments mentioned here regarding the alignment of the first side in relation to the second side of the material unit have the advantages explained above.

The material unit is made of any desired material and/or includes the material that is suitable for holding the object. In yet another embodiment of the particle beam apparatus according to the system described herein, it is additionally or alternatively provided that the material unit is in the form of a conductive material unit and/or in the form of a metal unit. In particular, it is provided that the material unit is in the form of a material unit including copper and/or a material unit made of copper. It has been shown that copper exhibits a particularly good material redeposition rate. Expressed differently, in the event of the ablation of material of a material unit made of copper or one including copper, it is especially the case that enough material is ablated for it to be possible to achieve a secure connection of the material unit both to the manipulator and to the object owing to the amount of material that is deposited. It is explicitly pointed out that the invention is not restricted to copper as the metal. Rather, the metal unit may include any metal and/or be made from any metal that is suitable for the invention. The same also applies to alloys.

In yet another embodiment of the particle beam apparatus according to the system described herein, it is additionally or alternatively provided that the material unit includes a first material part and a second material part, with the first material part being arranged on the second material part. Expressed differently, the material unit has a multi-part form, with the material unit including at least the first material part and at least the second material part. Accordingly, the material unit may have more than two material parts. For example, the first material part is aligned in relation to the second material part in such a way that the angle between the first material part and the second material part is not 0° or 180°. In particular, it is provided that the angle between the first material part and the second material part is 90° or substantially 90°. It is pointed out that the invention is not restricted to the aforementioned angles. Rather, any angle that is suitable for the invention can be used. With regard to the multi-part form of the material unit, reference is made to the comments above, which also apply here. Regarding the formation of the first material part and/or the second material part, reference is also made to the comments relating to the formation of the material unit above and below, which also apply here.

In one embodiment of the particle beam apparatus according to the system described herein, it is additionally or alternatively provided that the particle beam apparatus has a first gas feed device for feeding a first gas and/or a second gas feed device for feeding a second gas. With regard to the formation to the first gas feed device and/or the second gas feed device, reference is made to the comments elsewhere herein, which also apply here.

In another embodiment of the particle beam apparatus according to the system described herein, it is additionally or alternatively provided that the particle beam apparatus has at least one heating and/or cooling device for setting a temperature of the manipulator and/or of the object and/or of the material unit. For example, the particle beam apparatus according to the system described herein has a first heating and/or cooling device which is provided to set the temperature of the manipulator (in particular for cooling purposes). The particle beam apparatus according to the system described herein also has for example a second heating and/or cooling device which is provided to set the temperature of the object (in particular for cooling purposes). Moreover, the particle beam apparatus according to the system described herein has for example a third heating and/or cooling device which is provided to set the temperature of the material unit (in particular for cooling purposes). In particular, the manipulator and/or the object and/or the material unit are/is cooled to a temperature of −140° C. or less than −140° C. using liquid nitrogen or liquid helium. Temperatures below −50° C. are referred to herein as cryo-temperatures.

In yet another embodiment of the particle beam apparatus according to the system described herein, the beam generator is in the form of a first beam generator and the particle beam is in the form of a first particle beam including first charged particles. The objective lens is also in the form of a first objective lens for focusing the first particle beam onto the object and/or onto the manipulator and/or onto the material unit. Moreover, the particle beam apparatus according to the system described herein has at least one second beam generator for generating a second particle beam including second charged particles. The particle beam apparatus according to the system described herein also has at least one second objective lens for focusing the second particle beam onto the object and/or the manipulator and/or the material unit.

In particular, it is provided that the particle beam apparatus is in the form of an electron beam apparatus and/or an ion beam apparatus.

The system described herein also relates to a device for fastening and/or moving an object in a particle beam apparatus. The device according to the system described herein has a movable manipulator and a material unit for fastening an object. The material unit is fastened to the manipulator.

In particular, it is provided that the manipulator is connected to a movement device to provide movability for the manipulator. For example, the movement device enables a movement of the manipulator in at least one specific direction. In particular, the movement device may have multiple translational movement units (for example 3 to 4 translational movement units) and/or multiple rotational movement units (for example 2 to 3 rotational movement units). For example, the manipulator is configured such that the manipulator is movable along a first translational movement axis (for example an x axis), along a second translational movement axis (for example a y axis), and along a third translational movement axis (for example a z axis). For example, the first translational movement axis, the second translational movement axis, and the third translational movement axis are oriented perpendicularly to one another. The manipulator may also be rotatable about a first axis of rotation and about a second axis of rotation, which is aligned perpendicularly to the first axis of rotation.

Any material unit that is suitable for holding the object can be used as material unit. For example, the material unit is in the form of a conductive material unit and/or a metal unit. In particular, it is provided that the material unit is in the form of a material unit including copper and/or a material unit made of copper. Reference is made to the comments above, which also apply here. It is explicitly pointed out that the invention is not restricted to copper as the metal. Rather, the metal unit may include any metal and/or be made from any metal that is suitable for the invention. The same also applies to alloys.

In another embodiment of the device according to the system described herein, it is additionally or alternatively provided that the material unit has a structural unit, which can be arranged on the object. In particular, it is provided that the structural unit has at least one projection, the projection being able to be arranged on the object. However, the invention is not restricted to the aforementioned structural unit. Rather, the material unit may be provided with any structural unit that is suitable for the invention. Reference is made to the comments elsewhere herein regarding the structural unit, which also apply here.

In yet another embodiment of the device according to the system described herein, it is additionally or alternatively provided that the material unit includes a first material part and a second material part, with the first material part being arranged on the second material part. Expressed differently, the material unit has a multi-part form, with the material unit including at least the first material part and at least the second material part. Accordingly, the material unit may have more than two material parts. For example, the first material part is aligned in relation to the second material part in such a way that the angle between the first material part and the second material part is not 0° or 180°. In particular, it is provided that the angle between the first material part and the second material part is 90° or substantially 90°. It is pointed out that the invention is not restricted to the aforementioned angles. Rather, any angle that is suitable for the invention can be used. With regard to the multi-part form of the material unit, reference is made to the comments above, which also apply here. Regarding the formation of the first material part and/or the second material part, reference is made to the comments elsewhere herein relating to the formation of the material unit, which also apply here.

### BRIEF DESCRIPTION OF DRAWINGS

Further practical embodiments and advantages of the system described herein are described below in conjunction with the drawings, in which:

FIG. 1 shows a first embodiment of a particle beam apparatus;

FIG. 2 shows a second embodiment of a particle beam apparatus;

FIG. 3 shows a third embodiment of a particle beam apparatus;

FIG. 4 shows a fourth embodiment of a particle beam apparatus;

FIG. 5 shows a fifth embodiment of a particle beam apparatus;

FIG. 6 shows a sixth embodiment of a particle beam apparatus;

FIG. 7 shows a schematic illustration of a manipulator;

FIG. 8 shows a schematic illustration of an object stage;

FIG. 9 shows a further schematic illustration of the object stage according to FIG. 8;

FIG. 10 shows a schematic illustration of a material unit;

FIG. 11 shows a schematic illustration of the procedure of one embodiment of a method for fastening and moving an object;

FIG. 12 shows a schematic illustration of a manipulator, a material unit and an object;

FIG. 13 shows a schematic illustration of the procedure of another embodiment of a method for fastening and moving an object;

FIG. 14 shows a schematic illustration of a material unit and an object;

FIG. 15 shows a schematic illustration of the procedure of yet another embodiment of a method for fastening and moving an object;

FIG. 16 shows a schematic illustration of the procedure of yet another embodiment of a method for fastening and moving an object; and

FIG. 17 shows a schematic illustration of a device for fastening and moving an object.

### DETAILED DESCRIPTION OF VARIOUS EMBODIMENTS

The system described herein will now be explained in more detail using particle beam apparatuses in the form of an SEM and in the form of a combination apparatus, which has an electron beam column and an ion beam column. It is expressly pointed out that the invention can be used for any particle beam apparatus, in particular for any electron beam apparatus and/or any ion beam apparatus.

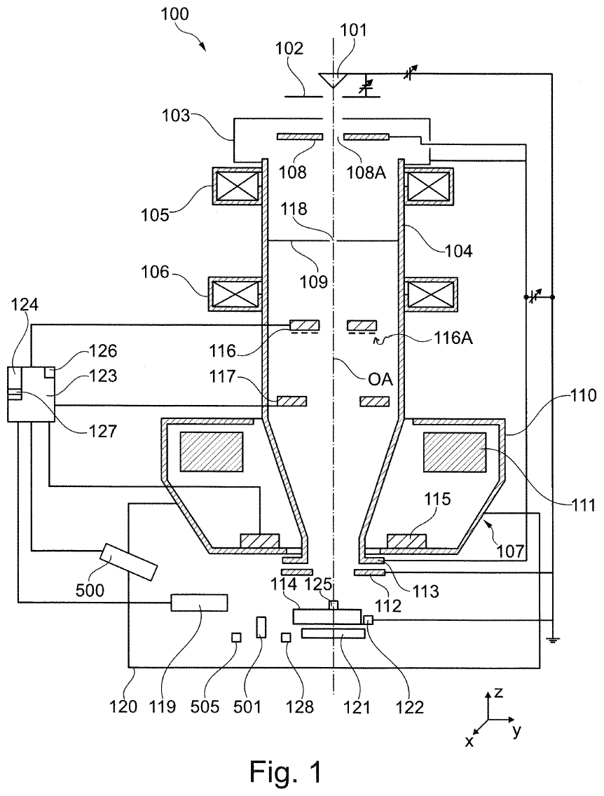

FIG. 1 shows a schematic illustration of an SEM 100. The SEM 100 has a first beam generator in the form of an electron source 101, which is in the form of a cathode. The SEM 100 is also provided with an extraction electrode 102 and with an anode 103, which is arranged on one end of a beam guiding tube 104 of the SEM 100. For example, the electron source 101 is in the form of a thermal field emitter. However, the invention is not restricted to such an electron source 101. Rather, any electron source can be used.

Electrons emerging from the electron source 101 form a primary electron beam. The electrons are accelerated to anode potential owing to a potential difference between the electron source 101 and the anode 103. In the embodiment illustrated here, the anode potential is 100 V to 35 kV, for example 5 kV to 15 kV, in particular 8 kV, relative to a ground potential of a housing of a sample chamber 120. However, alternatively the anode potential could also be at ground potential.

Two condenser lenses, specifically a first condenser lens 105 and a second condenser lens 106, are arranged on the beam guiding tube 104. Here, proceeding from the electron source 101 as viewed in the direction of a first objective lens 107, the first condenser lens 105 comes first, followed by the second condenser lens 106. It is expressly pointed out that further embodiments of the SEM 100 may include only a single condenser lens. A first aperture unit 108 is arranged between the anode 103 and the first condenser lens 105. Together with the anode 103 and the beam guiding tube 104, the first aperture unit 108 is at a high-voltage potential, specifically the potential of the anode 103, or connected to ground. The first aperture unit 108 has numerous first apertures 108A, one of which is illustrated in FIG. 1. For example, two first apertures 108A are present. Each one of the numerous first apertures 108A has a different aperture diameter. Using an adjustment mechanism (not illustrated), it is possible to set a desired first aperture 108A onto an optical axis OA of the SEM 100. It is explicitly pointed out that, in further embodiments, the first aperture unit 108 may be provided with only a single aperture 108A. In an embodiment with a single aperture, it is possible that an adjustment mechanism is not provided so that first aperture unit 108 is stationary. A stationary second aperture unit 109 is arranged between the first condenser lens 105 and the second condenser lens 106. As an alternative, it is provided that the second aperture unit 109 is movable.

The first objective lens 107 has pole pieces 110, in which a hole is formed. The beam guiding tube 104 is guided through the hole. A coil 111 is arranged in the pole pieces 110.

An electrostatic retardation device is arranged in a lower region of the beam guiding tube 104. The electrostatic retardation device includes a single electrode 112 and a tube electrode 113. The tube electrode 113 is arranged at an end of the beam guiding tube 104 that faces an object 125 that is arranged on a movable object holder 114.

Together with the beam guiding tube 104, the tube electrode 113 is at the potential of the anode 103, while the single electrode 112 and the object 125 are at a lower potential than the potential of the anode 103. In the present case, the lower potential is the ground potential of the housing of the sample chamber 120. In this way, the electrons of the primary electron beam can be decelerated to a desired energy which is required for examining the object 125.

The SEM 100 also has a scanning device 115 that deflects and scans the primary electron beam over the object 125. Here, the electrons of the primary electron beam interact with the object 125. The interaction results in interaction particles, which are detected. In particular, electrons are emitted from the surface of the object 125—so-called secondary electrons—or electrons of the primary electron beam are back scattered—so-called back scattered electrons—as interaction particles.

The object 125 and the single electrode 112 can also be at different potentials and potentials that differ from ground. This makes it possible to set the location of the retardation of the primary electron beam in relation to the object 125. If, for example, the retardation is carried out quite close to the object 125, imaging aberrations become smaller.

A detector arrangement including a first detector 116 and a second detector 117 is arranged in the beam guiding tube 104 to detect the secondary electrons and/or the back scattered electrons. Here, the first detector 116 is arranged on the source side along the optical axis OA, while the second detector 117 is arranged on the object side along the optical axis OA in the beam guiding tube 104. The first detector 116 and the second detector 117 are offset from one another in the direction of the optical axis OA of the SEM 100. Both the first detector 116 and the second detector 117 have a respective through opening, through which the primary electron beam can pass. The first detector 116 and the second detector 117 are approximately at the potential of the anode 103 and of the beam guiding tube 104. The optical axis OA of the SEM 100 runs through the respective through openings.

The second detector 117 serves mainly for detection of secondary electrons. Upon emerging from the object 125, the secondary electrons initially have a low kinetic energy and random directions of movement. Using the strong extraction field emanating from the tube electrode 113, the secondary electrons are accelerated in the direction of the first objective lens 107. The secondary electrons enter the first objective lens 107 approximately parallel. The beam diameter of the beam of the secondary electrons remains small in the first objective lens 107 as well. The first objective lens 107 then has a strong effect on the secondary electrons and generates a comparatively short focus of the secondary electrons with sufficiently steep angles with respect to the optical axis OA, such that the secondary electrons diverge far apart from one another downstream of the focus and strike the active area of the second detector 117. By contrast, only a small proportion of electrons that are back scattered at the object 125—that is to say back scattered electrons which have a relatively high kinetic energy in comparison with the secondary electrons upon emerging from the object 125—are detected by the second detector 117. The high kinetic energy and the angles of the back scattered electrons with respect to the optical axis OA upon emerging from the object 125 have the effect that a beam waist, which is to say a beam region having a minimum diameter, of the back scattered electrons lies in the vicinity of the second detector 117. A large portion of the back scattered electrons passes through the through opening of the second detector 117. Therefore, the first detector 116 substantially serves to detect the back scattered electrons.

In a further embodiment of the SEM 100, the first detector 116 can additionally be designed with an opposing field grid 116A. The opposing field grid 116A is arranged on the side of the first detector 116 that faces toward the object 125. With respect to the potential of the beam guiding tube 104, the opposing field grid 116A has a negative potential such that only back scattered electrons with high energy pass through the opposing field grid 116A to the first detector 116. In addition or as an alternative, the second detector 117 has a further opposing field grid, which is configured similarly to the aforementioned opposing field grid 116A of the first detector 116 and has a similar function.

The detection signals generated by the first detector 116 and the second detector 117 are used to generate an image or images of the surface of the object 125.

It is expressly pointed out that the apertures of the first aperture unit 108 and of the second aperture unit 109, as well as the through openings of the first detector 116 and of the second detector 117, are illustrated in exaggerated fashion. The through openings of the first detector 116 and of the second detector 117 have an extent perpendicular to the optical axis OA in the range of 0.5 mm to 5 mm. For example, the through openings of the first detector 116 and of the second detector 117 are circular and have a diameter in the range of 1 mm to 3 mm perpendicular to the optical axis OA.

The second aperture unit 109 is in the form of a pinhole stop in the embodiment illustrated here and is provided with a second aperture 118 for the passage of the primary electron beam, which has an extent in the range of 5 μm to 500 μm, for example 35 μm. As an alternative, in another embodiment it is provided that the second aperture unit 109 is provided with multiple apertures, which can be displaced mechanically with respect to the primary electron beam or which can be reached by the primary electron beam using electrical and/or magnetic deflection elements. The second aperture unit 109 is in the form of a pressure stage aperture unit, which separates a first region, in which the electron source 101 is arranged and in which there is an ultra-high vacuum (10⁻⁷ hPa to 10⁻¹² hPa), from a second region, which has a high vacuum (10⁻³ hPa to 10⁻⁷ hPa). The second region is the intermediate pressure region of the beam guiding tube 104, which leads to the sample chamber 120.

The sample chamber 120 is under vacuum. To generate the vacuum, a pump (not illustrated) is arranged on the sample chamber 120. In the embodiment illustrated in FIG. 1, the sample chamber 120 is operated in a first pressure range or in a second pressure range. The first pressure range includes only pressures of less than or equal to 10⁻³ hPa, and the second pressure range includes only pressures of greater than 10⁻³ hPa. To ensure the first and second pressure ranges, the sample chamber 120 is vacuum-sealed.

The object holder 114 is arranged on an object stage 122. The object stage 122 is movable in three directions which are perpendicular to one another, specifically in an x direction (first stage axis), in a y direction (second stage axis) and in a z direction (third stage axis). Moreover, the object stage 122 can be rotated about two axes of rotation (axes of rotation of the stage) which are perpendicular to one another. The invention is not restricted to the object stage 122 described above. Rather, the object stage 122 may have further translational movement axes and axes of rotation along which or about which the object stage 122 can move.

The SEM 100 also has a third detector 121, which is arranged in the sample chamber 120. More precisely, the third detector 121 is downstream of the object stage 122 as viewed from the electron source 101 along the optical axis OA. The object stage 122, and hence the object holder 114, can be rotated in such a way that the primary electron beam can pass through the object 125 arranged on the object holder 114. When the primary electron beam passes through the object 125 to be examined, the electrons of the primary electron beam interact with the material of the object 125 to be examined. The electrons passing through the object 125 to be examined are detected by the third detector 121.

A radiation detector 119, which is used to detect interaction radiation, for example x-ray radiation and/or cathodoluminescent light, is arranged in the sample chamber 120. The radiation detector 119, the first detector 116 and the second detector 117 are connected to a control unit 123, which has a monitor 124 and a processor 127. The third detector 121 is also connected to the control unit 123. This is not illustrated for reasons of clarity. In addition or as an alternative, a further detector in the form of a chamber detector 500, in particular for detection of secondary electrons, may be arranged in the sample chamber 120. The further detector is likewise connected to the control unit 123. The control unit 123 processes detection signals that are generated by the first detector 116, the second detector 117, the third detector 121, the radiation detector 119, and/or the chamber detector 500 and displays the detection signals in the form of images on the monitor 124.

The control unit 123 also has a database 126, in which data are stored and from which data are read out.

A first heating and/or cooling device 128, which is used to cool and/or heat the object holder 114 and hence the object 125 arranged there, is arranged on the object holder 114. For example, the object holder 114 is cooled to a temperature of −140° C. or less than −140° C. using liquid nitrogen or liquid helium. A temperature measuring unit (not illustrated) is arranged in the sample chamber 120 in order to determine the temperature of the object 125. For example, the temperature measuring unit is in the form of an infrared measuring apparatus or a semiconductor temperature sensor. However, the invention is not restricted to the use of such temperature measuring units. Rather, any temperature measuring unit which is suitable for the invention can be used as temperature measuring unit.

The SEM 100 also has a movable manipulator 501, which is illustrated only schematically in FIG. 1. The manipulator 501 is configured to hold and/or move the object 125 or a part of the object 125. The SEM 100 also has a material unit 505, which is illustrated schematically in FIG. 1. The manipulator 501 and the material unit 505 are explained in more detail below.

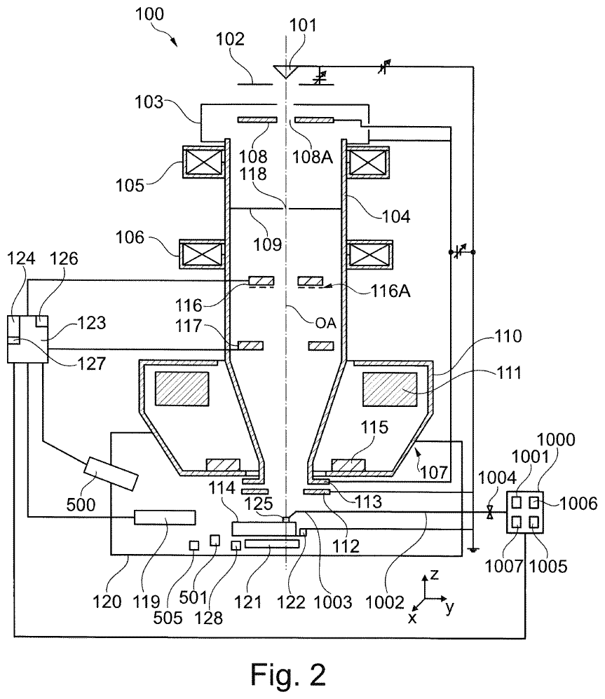

FIG. 2 shows a schematic illustration of a further SEM 100. The embodiment in FIG. 2 is based on the embodiment in FIG. 1. Identical components are provided with identical reference signs. By contrast to the embodiment of the SEM 100 according to FIG. 1, the SEM 100 according to FIG. 2 has a gas feed device 1000. The gas feed device 1000 serves to feed a gaseous precursor to a specific position on the surface of the object 125 or of a unit, explained below, of the SEM 100. The gas feed device 1000 has a precursor reservoir 1001. For example, the precursor is stored as a solid or liquid substance in the precursor reservoir 1001. In order to bring the precursor into the gaseous state, the precursor is evaporated or sublimated inside the precursor reservoir 1001. For example, evaporating or sublimating can be influenced by controlling the temperature of the precursor reservoir 1001 and/or of the precursor. As an alternative, the precursor is stored in the precursor reservoir 1001 as a gaseous substance. For example, a precursor including metal is used as precursor in order to deposit a metal or a metal-containing layer on the surface of the object 125. For example, a non-conductive material, in particular SiO₂, may also be deposited on the surface of the object 125. Furthermore, it is also provided that the precursor is used to ablate material of the object 125 upon interaction with a particle beam.

The gas feed device 1000 is provided with a feed line 1002. The feed line 1002 has, in the direction of the object 125, an acicular and/or capillary device, for example in the form of a hollow tube 1003, which in particular can be brought close to the surface of the object 125, for example to a distance of 10 μm to 1 mm from the surface of the object 125. The hollow tube 1003 has a feed opening, the diameter of which is for example in the range of 10 μm to 1000 μm, in particular in the range of 100 μm to 600 μm. The feed line 1002 has a valve 1004 in order to regulate the flow rate of gaseous precursor into the feed line 1002. Expressed differently, when the valve 1004 is opened, the gaseous precursor from the precursor reservoir 1001 is introduced into the feed line 1002 and guided via the hollow tube 1003 to the surface of the object 125. When the valve 1004 is closed, the inflow of the gaseous precursor onto the surface of the object 125 is stopped.

The gas feed device 1000 is also provided with an adjustment unit 1005, which enables adjustment of the position of the hollow tube 1003 in all three spatial directions—specifically an x direction, a y direction and a z direction—and adjustment of the orientation of the hollow tube 1003 by way of rotation and/or tilting. The gas feed device 1000 and hence also the adjustment unit 1005 are connected to the control unit 123 of the SEM 100.

In further embodiments, the precursor reservoir 1001 is not arranged directly on the gas feed device 1000. Rather, in the further embodiments, it is provided that the precursor reservoir 1001 is arranged for example on a wall of a room in which the SEM 100 is situated. As an alternative, it is provided that the precursor reservoir 1001 is arranged in a first room and the SEM 100 is arranged in a second room separate from the first room. As yet another alternative, it is provided that the precursor reservoir 1001 is arranged in a cabinet device.

The gas feed device 1000 includes a temperature measuring unit 1006. For example, a resistance measuring device, a thermocouple and/or a semiconductor temperature sensor are/is used as temperature measuring unit 1006. However, the invention is not restricted to the use of such temperature measuring units 1006. Rather, any temperature measuring unit that is suitable for the invention can be used as temperature measuring unit 1006. In particular, it may be provided that the temperature measuring unit 1006 is not arranged on the gas feed device 1000, but rather is arranged for example at a distance from the gas feed device 1000.

The gas feed device 1000 further includes a temperature setting unit 1007. For example, the temperature setting unit 1007 is a heating device, in particular a conventional infrared heating device, a heating wire and/or a Peltier element. As an alternative, the temperature setting unit 1007 is in the form of a heating and/or cooling device which includes a heating wire, for example. However, the invention is not restricted to the use of such a temperature setting unit 1007. Rather, any suitable temperature setting unit can be used for the invention.

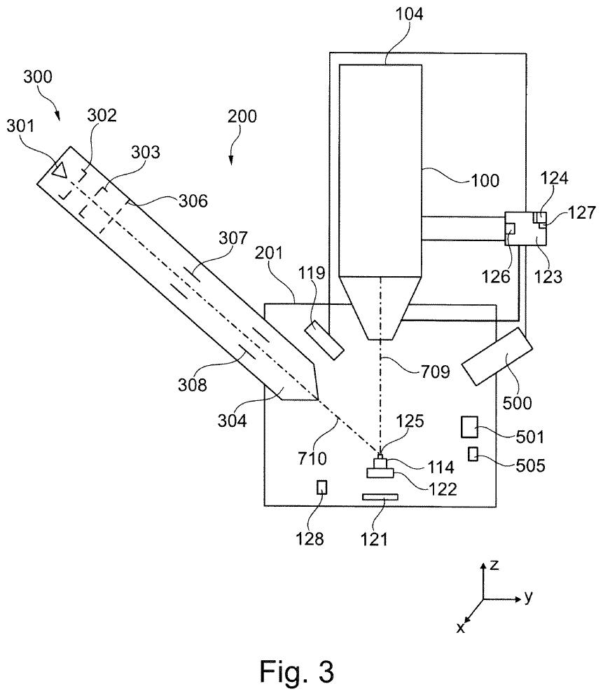

FIG. 3 shows a particle beam apparatus in the form of a combination apparatus 200. The combination apparatus 200 includes two particle beam columns. For the one part, the combination apparatus 200 is provided with the SEM 100, as illustrated in FIG. 1, but without the sample chamber 120. Rather, the SEM 100 is arranged on a sample chamber 201. The sample chamber 201 is under vacuum. To generate the vacuum, a pump (not illustrated) is arranged on the sample chamber 201. In the embodiment illustrated in FIG. 3, the sample chamber 201 is operated in a first pressure range or in a second pressure range. The first pressure range includes only pressures of less than or equal to 10⁻³ hPa, and the second pressure range includes only pressures of greater than 10⁻³ hPa. To ensure the first and second pressure ranges, the sample chamber 201 is vacuum-sealed.

The third detector 121 is arranged in the sample chamber 201.

The SEM 100 serves to generate a first particle beam, specifically the primary electron beam described above, and has the optical axis mentioned above, which is provided with the reference sign 709 in FIG. 3 and is also referred to as first beam axis below. For the other part, the combination apparatus 200 is provided with an ion beam apparatus 300, which is likewise arranged on the sample chamber 201. The ion beam apparatus 300 likewise has an optical axis, which is provided with the reference sign 710 in FIG. 3 and is also referred to as second beam axis below.

The SEM 100 is arranged vertically in relation to the sample chamber 201. By contrast, the ion beam apparatus 300 is inclined by an angle of approximately 0° to 90° in relation to the SEM 100. For example, an arrangement of approximately 50° is illustrated in FIG. 3. The ion beam apparatus 300 includes a second beam generator in the form of an ion beam generator 301. Ions, which form a second particle beam in the form of an ion beam, are generated by the ion beam generator 301. The ions are accelerated using an extraction electrode 302, which is at a predefinable potential. The second particle beam then passes through an ion optical unit of the ion beam apparatus 300, the ion optical unit including a condenser lens 303 and a second objective lens 304. The second objective lens 304 ultimately generates an ion probe, which is focused onto the object 125 that is arranged on an object holder 114. The object holder 114 is arranged on an object stage 122.

A settable or selectable aperture unit 306, a first electrode arrangement 307 and a second electrode arrangement 308 are arranged above the second objective lens 304 (that is to say in the direction of the ion beam generator 301), with the first electrode arrangement 307 and the second electrode arrangement 308 being in the form of scanning electrodes. The second particle beam is scanned over the surface of the object 125 using the first electrode arrangement 307 and the second electrode arrangement 308, with the first electrode arrangement 307 acting in a first direction and the second electrode arrangement 308 acting in a second direction, which is counter to the first direction. Hence, the scanning is carried out for example in a first direction. The scanning in a second direction perpendicular to the first direction is effected by further electrodes (not illustrated), which are rotated by 90°, on the first electrode arrangement 307 and on the second electrode arrangement 308.

As explained above, the object holder 114 is arranged on the object stage 122. It is also the case in the embodiment shown in FIG. 3 that the object stage 122 is movable in three directions which are perpendicular to one another, specifically in an x direction (first stage axis), in a y direction (second stage axis) and in a z direction (third stage axis). Moreover, the object stage 122 can be rotated about two axes of rotation (axes of rotation of the stage) which are perpendicular to one another.

The distances illustrated in FIG. 3 between the individual units of the combination apparatus 200 are illustrated in exaggerated fashion in order to better illustrate the individual units of the combination apparatus 200.

A radiation detector 119, which is used to detect interaction radiation, for example x-ray radiation and/or cathodoluminescent light, is arranged in the sample chamber 201. The radiation detector 119 is connected to a control unit 123, which includes a monitor 124 and a processor 127. In addition or as an alternative, a further detector in the form of a chamber detector 500, in particular for detection of secondary electrons, may be arranged in the sample chamber 201. The further detector is likewise connected to the control unit 123.

The control unit 123 processes detection signals that are generated by the first detector 116, the second detector 117 (not illustrated in FIG. 3), the third detector 121, the radiation detector 119, and/or the chamber detector 500 and displays the detection signals in the form of images on the monitor 124.

The control unit 123 also has a database 126, in which data are stored and from which data are read out.

A first heating and/or cooling device 128, which is used to cool and/or heat the object holder 114 and hence the object 125 arranged in the object holder 114, is arranged on the object holder 114. For example, the object holder 114 is cooled to a temperature of −140° C. or less than −140° C. using liquid nitrogen or liquid helium. A temperature measuring unit (not illustrated) is arranged in the sample chamber 201 in order to determine the temperature of the object 125. For example, the temperature measuring unit is in the form of an infrared measuring apparatus or a semiconductor temperature sensor. However, the invention is not restricted to the use of such temperature measuring units. Rather, any temperature measuring unit which is suitable for the invention can be used as temperature measuring unit.

The combination apparatus 200 also has a movable manipulator 501, which is illustrated only schematically in FIG. 3. The manipulator 501 is configured to hold and/or move the object 125 or a part of the object 125. The combination apparatus 200 also has a material unit 505, which is illustrated schematically in FIG. 3. The manipulator 501 and the material unit 505 are explained in more detail below.

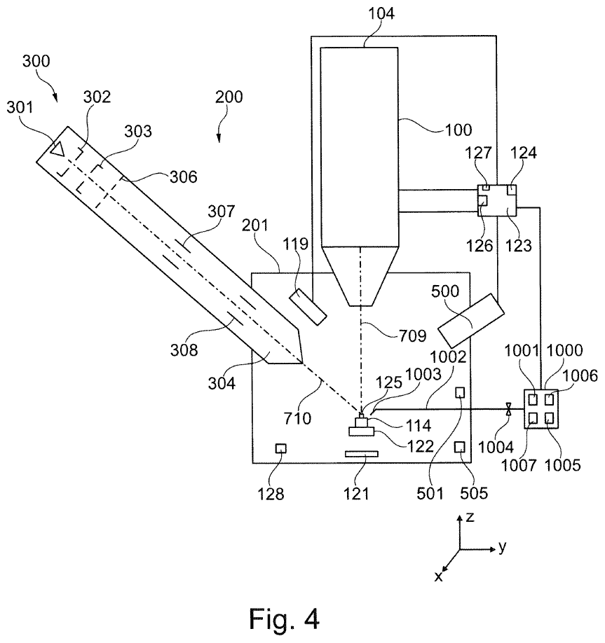

FIG. 4 shows a schematic illustration of a further combination apparatus 200. The embodiment in FIG. 4 is based on the embodiment in FIG. 3. Identical components are provided with identical reference signs. By contrast to the embodiment of the combination apparatus 200 according to FIG. 3, the combination apparatus 200 according to FIG. 4 has a gas feed device 1000. The gas feed device 1000 serves to feed a gaseous precursor to a specific position on the surface of the object 125 or of a unit, explained below, of the combination apparatus 200. The gas feed device 1000 has a precursor reservoir 1001. For example, the precursor is stored as a solid or liquid substance in the precursor reservoir 1001. In order to bring the precursor into the gaseous state, the precursor is evaporated or sublimated inside the precursor reservoir 1001. For example, evaporating or sublimating can be influenced by controlling the temperature of the precursor reservoir 1001 and/or of the precursor. As an alternative, the precursor is stored in the precursor reservoir 1001 as a gaseous substance. For example, a precursor including metal is used as precursor in order to deposit a metal or a metal-containing layer on the surface of the object 125. For example, a non-conductive material, in particular SiO₂, may also be deposited on the surface of the object 125. Furthermore, it is also provided that the precursor is used to ablate material of the object 125 upon interaction with the particle beam.

The gas feed device 1000 is provided with a feed line 1002. The feed line 1002 has, in the direction of the object 125, an acicular and/or capillary device, for example in the form of a hollow tube 1003, which in particular can be brought close to the surface of the object 125, for example to a distance of 10 μm to 1 mm from the surface of the object 125. The hollow tube 1003 has a feed opening, the diameter of which is for example in the range of 10 μm to 1000 μm, in particular in the range of 100 μm to 600 μm. The feed line 1002 has a valve 1004 in order to regulate the flow rate of gaseous precursor into the feed line 1002. Expressed differently, when the valve 1004 is opened, gaseous precursor from the precursor reservoir 1001 is introduced into the feed line 1002 and guided via the hollow tube 1003 to the surface of the object 125. When the valve 1004 is closed, the inflow of the gaseous precursor onto the surface of the object 125 is stopped.

The gas feed device 1000 is also provided with an adjustment unit 1005, which enables adjustment of the position of the hollow tube 1003 in all three spatial directions—specifically an x direction, a y direction and a z direction—and adjustment of the orientation of the hollow tube 1003 by way of rotation and/or tilting. The gas feed device 1000 and hence also the adjustment unit 1005 are connected to the control unit 123 of the SEM 100.

In further embodiments, the precursor reservoir 1001 is not arranged directly on the gas feed device 1000. Rather, in the further embodiments, it is provided that the precursor reservoir 1001 is arranged for example on a wall of a room in which the combination apparatus 200 is situated. As an alternative, it is provided that the precursor reservoir 1001 is arranged in a first room and the combination apparatus 200 is arranged in a second room separate from the first room. In yet another alternative, it is provided that the precursor reservoir 1001 is arranged in a cabinet device.

The gas feed device 1000 includes a temperature measuring unit 1006. For example, a resistance measuring device, a thermocouple and/or a semiconductor temperature sensor are/is used as temperature measuring unit 1006. However, the invention is not restricted to the use of such temperature measuring units 1006. Rather, any temperature measuring unit that is suitable for the invention can be used as temperature measuring unit 1006. In particular, it may be provided that the temperature measuring unit 1006 is not arranged on the gas feed device 1000, but rather is arranged for example at a distance from the gas feed device 1000.

The gas feed device 1000 further includes a temperature setting unit 1007. For example, the temperature setting unit 1007 is a heating device, in particular a conventional infrared heating device, a heating wire and/or a Peltier element. As an alternative, the temperature setting unit 1007 is in the form of a heating and/or cooling device which includes a heating wire, for example. However, the invention is not restricted to the use of such a temperature setting unit 1007. Rather, any suitable temperature setting unit can be used for the invention.

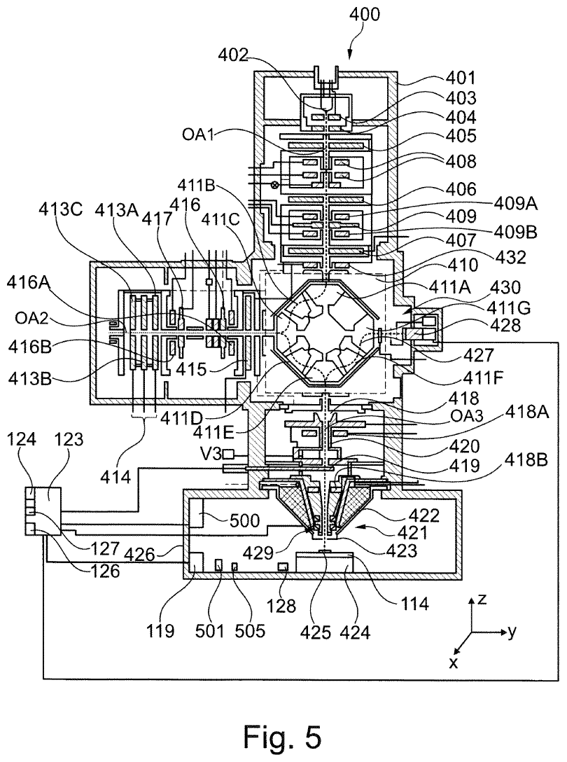

FIG. 5 is a schematic illustration of another embodiment of a particle beam apparatus according to the system described herein. The illustrated embodiment of the particle beam apparatus is provided with the reference sign 400 and includes a mirror corrector for correcting chromatic and/or spherical aberrations, for example. The particle beam apparatus 400 includes a particle beam column 401, which is in the form of an electron beam column and substantially corresponds to an electron beam column of a corrected SEM. However, the particle beam apparatus 400 is not restricted to an SEM with a mirror corrector. Rather, the particle beam apparatus can include any type of corrector units.

The particle beam column 401 includes a particle beam generator in the form of an electron source 402 (cathode), an extraction electrode 403, and an anode 404. For example, the electron source 402 is in the form of a thermal field emitter. Electrons emerging from the electron source 402 are accelerated to the anode 404 owing to a potential difference between the electron source 402 and the anode 404. Accordingly, a particle beam in the form of an electron beam is formed along a first optical axis OA1.

The particle beam is guided along a beam path, which corresponds to the first optical axis OA1, after the particle beam has emerged from the electron source 402. A first electrostatic lens 405, a second electrostatic lens 406, and a third electrostatic lens 407 are used to guide the particle beam.

Furthermore, the particle beam is set along the beam path using a beam guiding device. The beam guiding device of the illustrated embodiment includes a source setting unit with two magnetic deflection units 408 arranged along the first optical axis OA1. Moreover, the particle beam apparatus 400 includes electrostatic beam deflection units. A first electrostatic beam deflection unit 409, which is also in the form of a quadrupole in another embodiment, is arranged between the second electrostatic lens 406 and the third electrostatic lens 407. The first electrostatic beam deflection unit 409 is likewise downstream of the magnetic deflection units 408. A first multi-pole unit 409A in the form of a first magnetic deflection unit is arranged on one side of the first electrostatic beam deflection unit 409. Moreover, a second multi-pole unit 409B in the form of a second magnetic deflection unit is arranged on the other side of the first electrostatic beam deflection unit 409. The first electrostatic beam deflection unit 409, the first multi-pole unit 409A and the second multi-pole unit 409B are set for the purpose of setting the particle beam with respect to the axis of the third electrostatic lens 407 and the entrance window of a beam deflection device 410. The first electrostatic beam deflection unit 409, the first multi-pole unit 409A, and the second multi-pole unit 409B can interact like a Wien filter. A further magnetic deflection element 432 is arranged at the entrance to the beam deflection device 410.

The beam deflection device 410 is used as a particle beam deflector, which deflects the particle beam in a specific manner. The beam deflection device 410 includes multiple magnetic sectors, specifically a first magnetic sector 411A, a second magnetic sector 411B, a third magnetic sector 411C, a fourth magnetic sector 411D, a fifth magnetic sector 411E, a sixth magnetic sector 411F, and a seventh magnetic sector 411G. The particle beam enters the beam deflection device 410 along the first optical axis OA1 and is deflected by the beam deflection device 410 in the direction of a second optical axis OA2. The beam is deflected using the first magnetic sector 411A, using the second magnetic sector 411B and using the third magnetic sector 411C through an angle of 30° to 120°. The second optical axis OA2 is oriented at the same angle with respect to the first optical axis OA1. The beam deflection device 410 also deflects the particle beam which is guided along the second optical axis OA2, to be precise in the direction of a third optical axis OA3. The beam deflection is provided by the third magnetic sector 411C, the fourth magnetic sector 411D, and the fifth magnetic sector 411E. In the embodiment in FIG. 5, the deflection with respect to the second optical axis OA2 and with respect to the third optical axis OA3 is provided by deflection of the particle beam at an angle of 90°. Hence, the third optical axis OA3 runs coaxially with the first optical axis OA1. However, it is pointed out that the particle beam apparatus 400 according to the system described herein is not restricted to deflection angles of 90°. Rather, any suitable deflection angle can be selected by the beam deflection device 410, for example 70° or 110°, such that the first optical axis does not run coaxially with the third optical axis OA3. As regards further details of the beam deflection device 410, reference is made to WO 2002/067286 A2.

After the particle beam has been deflected by the first magnetic sector 411A, the second magnetic sector 411B, and the third magnetic sector 411C, the particle beam is guided along the second optical axis OA2. The particle beam is guided to an electrostatic mirror 414 and travels on a path to the electrostatic mirror 414 along a fourth electrostatic lens 415, a third multi-pole unit 416A in the form of a magnetic deflection unit, a second electrostatic beam deflection unit 416, a third electrostatic beam deflection unit 417, and a fourth multi-pole unit 416B in the form of a magnetic deflection unit. The electrostatic mirror 414 includes a first mirror electrode 413A, a second mirror electrode 413B, and a third mirror electrode 413C. Electrons of the particle beam which are reflected back at the electrostatic mirror 414 once again travel along the second optical axis OA2 and re-enter the beam deflection device 410. Then, the electrons are deflected with respect to the third optical axis OA3 by the third magnetic sector 411C, the fourth magnetic sector 411D, and the fifth magnetic sector 411E.

The electrons of the particle beam emerge from the beam deflection device 410 and are guided along the third optical axis OA3 to an object 425 that is to be examined, which is arranged in an object holder 114. On the path to the object 425, the particle beam is guided to a fifth electrostatic lens 418, a beam guiding tube 420, a fifth multi-pole unit 418A, a sixth multi-pole unit 418B, and an objective lens 421. The fifth electrostatic lens 418 is an electrostatic immersion lens. The particle beam is decelerated or accelerated to an electric potential of the beam guiding tube 420 by the fifth electrostatic lens 418.

The particle beam is focused by the objective lens 421 into a focal plane in which the object 425 is arranged. The object holder 114 is arranged on a movable object stage 424. The movable object stage 424 is arranged in a sample chamber 426 of the particle beam apparatus 400. The object stage 424 is movable in three directions which are perpendicular to one another, specifically in an x direction (first stage axis), in a y direction (second stage axis) and in a z direction (third stage axis). Moreover, the object stage 424 can be rotated about two axes of rotation (axes of rotation of the stage) which are perpendicular to one another.

The sample chamber 426 is under vacuum. To generate the vacuum, a pump (not illustrated) is arranged on the sample chamber 426. In the embodiment illustrated in figure the sample chamber 426 is operated in a first pressure range or in a second pressure range. The first pressure range includes only pressures of less than or equal to 10⁻³ hPa, and the second pressure range includes only pressures of greater than 10⁻³ hPa. To ensure the first and second pressure ranges, the sample chamber 426 is vacuum-sealed.

The objective lens 421 may be in the form of a combination of a magnetic lens 422 and a sixth electrostatic lens 423. The end of the beam guiding tube 420 may also be an electrode of an electrostatic lens. After emerging from the beam guiding tube 420, particles of the particle beam are decelerated to a potential of the object 425. The objective lens 421 is not restricted to a combination of the magnetic lens 422 and the sixth electrostatic lens 423. Rather, the objective lens 421 can assume any suitable form. For example, the objective lens 421 may also be in the form of a purely magnetic lens or a purely electrostatic lens.

The particle beam which is focused onto the object 425 interacts with the object 425. Interaction particles are generated. In particular, secondary electrons are emitted from the object 425 or back scattered electrons are back scattered at the object 425. The secondary electrons or the back scattered electrons are accelerated again and guided into the beam guiding tube 420 along the third optical axis OA3. In particular, the trajectories of the secondary electrons and the back scattered electrons extend on the route of the beam path of the particle beam in the opposite direction to the particle beam.

The particle beam apparatus 400 includes a first analysis detector 419, which is arranged between the beam deflection device 410 and the objective lens 421 along the beam path. Secondary electrons travelling in directions oriented at a large angle with respect to the third optical axis OA3 are detected by the first analysis detector 419. Back scattered electrons and secondary electrons which are at a small axial distance with respect to the third optical axis OA3 at the location of the first analysis detector 419—i.e., back scattered electrons and secondary electrons which are at a small distance from the third optical axis at the location of the first analysis detector 419—enter the beam deflection device 410 and are deflected to a second analysis detector 428 by the fifth magnetic sector 411E, the sixth magnetic sector 411F, and the seventh magnetic sector 411G along a detection beam path 427. For example, the deflection angle is 90° or 110°.

The first analysis detector 419 generates detection signals which are largely generated by emitted secondary electrons. The detection signals which are generated by the first analysis detector 419 are guided to a control unit 123 and are used to obtain information about the properties of the region of interaction of the focused particle beam with the object 425. In particular, the focused particle beam is scanned over the object 425 using a scanning device 429. Using the detection signals generated by the first analysis detector 419, an image of the scanned region of the object 425 can then be generated and displayed on a display unit. The display unit is, for example, a monitor 124 that is generated on the control unit 123. The control unit 123 additionally includes a processor 127.

The second analysis detector 428 is also connected to the control unit 123. Detection signals from the second analysis detector 428 are passed to the control unit 123 and used to generate an image of the scanned region of the object 425 and to display the image on a display unit. The display unit is for example the monitor 124 that is arranged on the control unit 123.

A radiation detector 119, which is used to detect interaction radiation, for example x-ray radiation and/or cathodoluminescent light, is arranged on the sample chamber 426. The radiation detector 119 is connected to the control unit 123, which includes the monitor 124. The control unit 123 processes detection signals of the radiation detector 119 and displays the detection signals in the form of images on the monitor 124.

The control unit 123 also has a database 126, in which data are stored and from which data are read out.

Moreover, the particle beam apparatus 400 has a chamber detector 500 which is connected to the control unit 123.

A first heating and/or cooling device 128, which is used to cool and/or heat the object holder 114 and hence the object 425 arranged there, is arranged on the object holder 114. For example, the object holder 114 is cooled to a temperature of −140° C. or less than −140° C. using liquid nitrogen or liquid helium. A temperature measuring unit (not illustrated) is arranged in the sample chamber 426 in order to determine the temperature of the object 425. For example, the temperature measuring unit is in the form of an infrared measuring apparatus or a semiconductor temperature sensor. However, the invention is not restricted to the use of such temperature measuring units. Rather, any temperature measuring unit which is suitable for the invention can be used as temperature measuring unit.

The particle beam apparatus 400 also has a movable manipulator 501, which is illustrated only schematically in FIG. 5. The manipulator 501 is configured to hold and/or move the object 425 or a part of the object 425. The particle beam apparatus 400 also has a material unit 505, which is illustrated schematically in FIG. 5. The manipulator 501 and the material unit 505 are explained in more detail below.

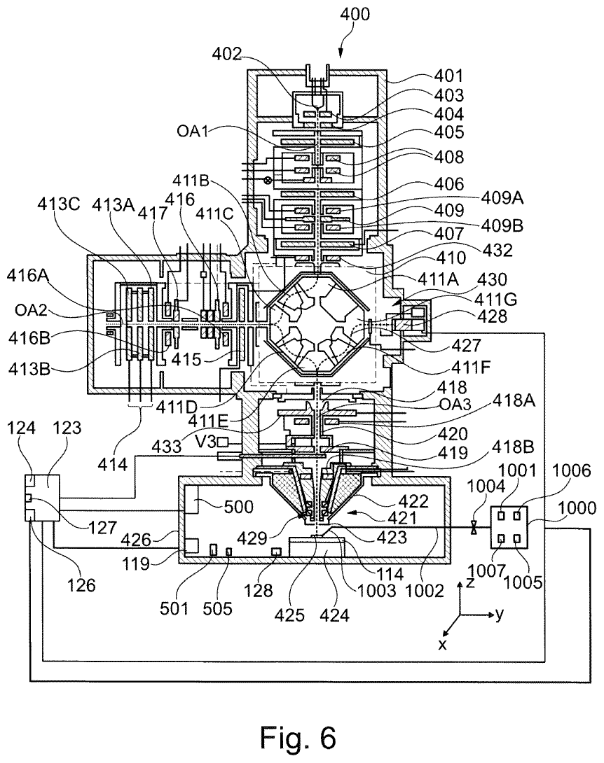

FIG. 6 shows a schematic illustration of a further particle beam apparatus 400. The embodiment in FIG. 6 is based on the embodiment in FIG. 5. Identical components are provided with identical reference signs. By contrast to the embodiment of the particle beam apparatus 400 according to FIG. 5, the combination apparatus according to FIG. 6 has a gas feed device 1000. The gas feed device 1000 serves to feed a gaseous precursor to a specific position on the surface of the object 425 or of a unit, explained below, of the particle beam apparatus 400. The gas feed device 1000 has a precursor reservoir 1001. For example, the precursor is stored as a solid or liquid substance in the precursor reservoir 1001. In order to bring the precursor into the gaseous state, the precursor is evaporated or sublimated inside the precursor reservoir 1001. For example, evaporating or sublimating can be influenced by controlling the temperature of the precursor reservoir 1001 and/or of the precursor. As an alternative, the precursor is stored in the precursor reservoir 1001 as a gaseous substance. For example, a precursor including metal is used as precursor in order to deposit a metal or a metal-containing layer on the surface of the object 425. For example, a non-conductive material, in particular SiO₂, may also be deposited on the surface of the object 425. Furthermore, it is also provided that the precursor is used to ablate material of the object 425 upon interaction with the particle beam.

The gas feed device 1000 is provided with a feed line 1002. The feed line 1002 has, in the direction of the object 425, an acicular and/or capillary device, for example in the form of a hollow tube 1003, which in particular can be brought close to the surface of the object 425, for example to a distance of 10 μm to 1 mm from the surface of the object 425. The hollow tube 1003 has a feed opening, the diameter of which is for example in the range of 10 μm to 1000 μm, in particular in the range of 100 μm to 600 μm. The feed line 1002 has a valve 1004 in order to regulate the flow rate of gaseous precursor into the feed line 1002. Expressed differently, when the valve 1004 is opened, gaseous precursor from the precursor reservoir 1001 is introduced into the feed line 1002 and guided via the hollow tube 1003 to the surface of the object 425. When the valve 1004 is closed, the inflow of the gaseous precursor onto the surface of the object 425 is stopped.

The gas feed device 1000 is also provided with an adjustment unit 1005, which enables adjustment of the position of the hollow tube 1003 in all three spatial directions—specifically an x direction, a y direction and a z direction—and adjustment of the orientation of the hollow tube 1003 by way of rotation and/or tilting. The gas feed device 1000 and hence also the adjustment unit 1005 are connected to the control unit 123 of the particle beam apparatus 400.

In further embodiments, the precursor reservoir 1001 is not arranged directly on the gas feed device 1000. Rather, in the further embodiments, it is provided that the precursor reservoir 1001 is arranged for example on a wall of a room in which the particle beam apparatus 400 is situated. As an alternative, it is provided that the precursor reservoir 1001 is arranged in a first room and the particle beam apparatus 400 is arranged in a second room separate from the first room. In yet another alternative, it is provided that the precursor reservoir 1001 is arranged in a cabinet device.

The gas feed device 1000 includes a temperature measuring unit 1006. For example, a resistance measuring device, a thermocouple and/or a semiconductor temperature sensor are/is used as temperature measuring unit 1006. However, the invention is not restricted to the use of such temperature measuring units 1006. Rather, any temperature measuring unit that is suitable for the invention can be used as temperature measuring unit 1006. In particular, it may be provided that the temperature measuring unit 1006 is not arranged on the gas feed device 1000, but rather is arranged for example at a distance from the gas feed device 1000.

The gas feed device 1000 further includes a temperature setting unit 1007. For example, the temperature setting unit 1007 is a heating device, in particular a conventional infrared heating device, a heating wire and/or a Peltier element. As an alternative, the temperature setting unit 1007 is in the form of a heating and/or cooling device which includes a heating wire, for example. However, the invention is not restricted to the use of such a temperature setting unit 1007. Rather, any suitable temperature setting unit can be used for the invention.

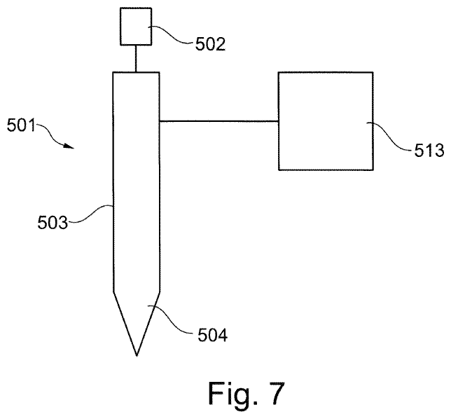

FIG. 7 shows a schematic illustration of one embodiment of the manipulator 501, which is used for example in the SEM 100 according to FIG. 1 or 2, in the combination apparatus 200 according to FIG. 3 or 4 and in the particle beam apparatus 400 according to FIG. 5 or 6. The manipulator 501 is configured to hold at least a part of the object 125, 425, to guide and/or to move the part of the object 125, 425. The manipulator 501 has a main body 503. One end 504 of the main body 503 is provided with a tip. The manipulator 501 is arranged on a movement device 513. The movement device 513 provides a movement of the manipulator 501. The movement device 513 makes it possible to move the manipulator 501 in three directions which are perpendicular to one another, specifically in an x direction, in a y direction and in a z direction. Moreover, the manipulator 501 can be rotated about two axes of rotation which are perpendicular to one another. The invention is not restricted to the above-described movements of the manipulator 501. Rather, the manipulator 501 may have further translational movement axes and axes of rotation along which or about which the manipulator 501 can move. The manipulator 501 may also have no axes of rotation and is accordingly not rotatable.

A second heating and/or cooling device 502, which is used to cool and/or heat the manipulator 501, is arranged on the manipulator 501. For example, a temperature measuring unit (not illustrated) for the manipulator 501 is arranged in the sample chamber 120, 201, 426 in order to determine a temperature of the object 125, 425 or of the manipulator 501. In particular, the temperature measuring unit is in the form of an infrared measuring apparatus or a semiconductor temperature sensor. However, the invention is not restricted to the use of such temperature measuring units. Rather, any temperature measuring unit which is suitable for the invention can be used as temperature measuring unit.

The invention is not restricted to a specific form of the manipulator 501. Rather, any manipulator 501 on which the material unit 505 can be arranged may be used in the invention. In another embodiment, the manipulator 501 has a main body 503 and an end 504, which adjoins the main body 503 and which is convex. In yet another embodiment of the manipulator 501, the manipulator 501 has a main body 503 and an end 504, which adjoins the main body 503 and which is flat. In this case, for example, a first side in the form of a longitudinal side of the manipulator 501 is ten times, fifteen times or twenty times larger than a second side in the form of a transverse side of the manipulator 501. In yet another embodiment of the manipulator 501, the manipulator 501 has a main body 503 and an end 504, which adjoins the main body 503 and which is concave.

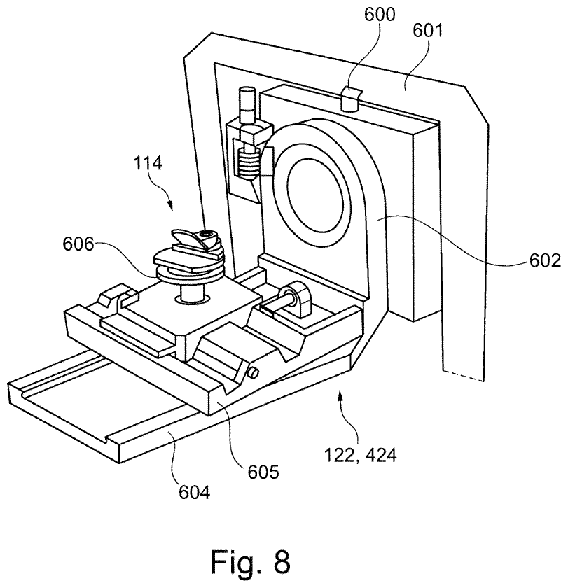

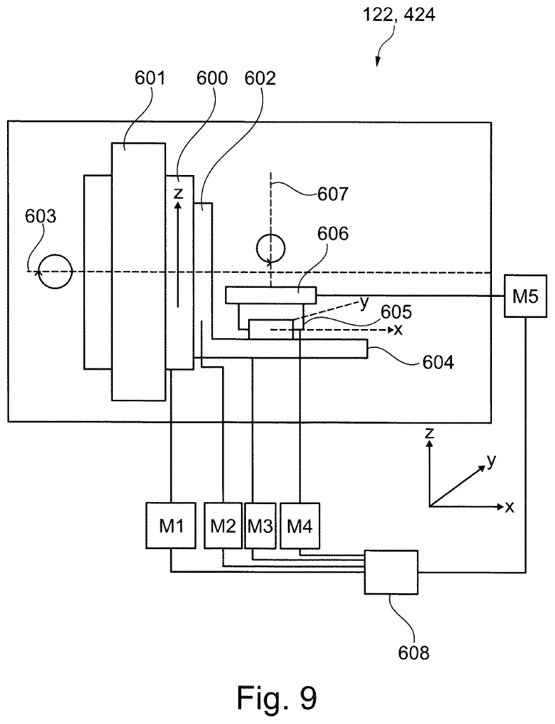

The object stage 122, 424 of the particle beam apparatuses 100, 200 and 400 explained above is discussed in detail below. The object stage 122, 424 is in the form of a movable object stage, which is illustrated schematically in FIGS. 8 and 9. It is pointed out that the invention is not restricted to the object stage 122, 424 described here. Rather, the invention can include any movable object stage that is suitable for the invention.

The object holder 114 is arranged on the object stage 122, 424. The object stage 122, 424 has movement elements that ensure a movement of the object stage 122, 424 in such a way that a region of interest on the object can be examined, for example using a particle beam. The movement elements are illustrated schematically in FIGS. 8 and 9 and are explained below.

The object stage 122, 424 has a first movement element 600, which is arranged, for example, on a housing 601 of the sample chamber 120, 201 or 426, in which in turn the object stage 122, 424 is arranged. The first movement element 600 enables a movement of the object stage 122, 424 along the z axis (third stage axis). A second movement element 602 is also provided. The second movement element 602 enables a rotation of the object stage 122, 424 about a first axis of rotation 603 of the stage, which is also referred to as a tilt axis. The second movement element 602 serves to tilt an object about the first axis of rotation 603 of the stage, the object being arranged on the object holder 114.

In turn, a third movement element 604, which is in the form of a guide for a carriage and ensures that the object stage 122, 424 is movable in the x direction (first stage axis), is arranged on the second movement element 602. The aforementioned carriage is in turn a further movement element, specifically a fourth movement element 605. The fourth movement element 605 is configured in such a way that the object stage 122, 424 is movable in the y direction (second stage axis). To this end, the fourth movement element 605 has a guide in which a further carriage is guided, on which in turn the object holder 114 is arranged.

The object holder 114 is in turn designed with a fifth movement element 606, which makes it possible to rotate the object holder 114 about a second axis of rotation 607 of the stage. The second axis of rotation 607 of the stage is oriented perpendicularly to the first axis of rotation 603 of the stage.

On account of the above-described arrangement, the object stage 122, 424 of the embodiment discussed here has the following kinematic chain: first movement element 600 (movement along the z axis)—second movement element 602 (rotation about the first axis of rotation 603 of the stage)—third movement element 604 (movement along the x axis)—fourth movement element 605 (movement along the y axis)—fifth movement element 606 (rotation about the second axis of rotation 607 of the stage).

In another embodiment (not illustrated), it is provided that further movement elements are arranged on the object stage 122, 424 such that movements along further translational movement axes and/or about further axes of rotation are made possible.

As can be seen in FIG. 9, each of the aforementioned movement elements is connected to a drive unit in the form of a motor M1 to M5. Thus, the first movement element 600 is connected to a first drive unit M1 and is driven owing to a driving force that is provided by the first drive unit M1. The second movement element 602 is connected to a second drive unit M2, which drives the second movement element 602. The third movement element 604 is connected, in turn, to a third drive unit M3. The third drive unit M3 provides a driving force for driving the third movement element 604. The fourth movement element 605 is connected to a fourth drive unit M4, with the fourth drive unit M4 driving the fourth movement element 605. Furthermore, the fifth movement element 606 is connected to a fifth drive unit M5. The fifth drive unit M5 provides a driving force that drives the fifth movement element 606.

The aforementioned drive units M1 to M5 may be in the form of stepper motors, for example, and are controlled by a drive control unit 608 and are each supplied with a supply current by the drive control unit 608 (cf. FIG. 9). It is explicitly pointed out that the invention is not restricted to the movement using stepper motors. Rather, any suitable drive units, for example brushless motors, can be used as drive units.

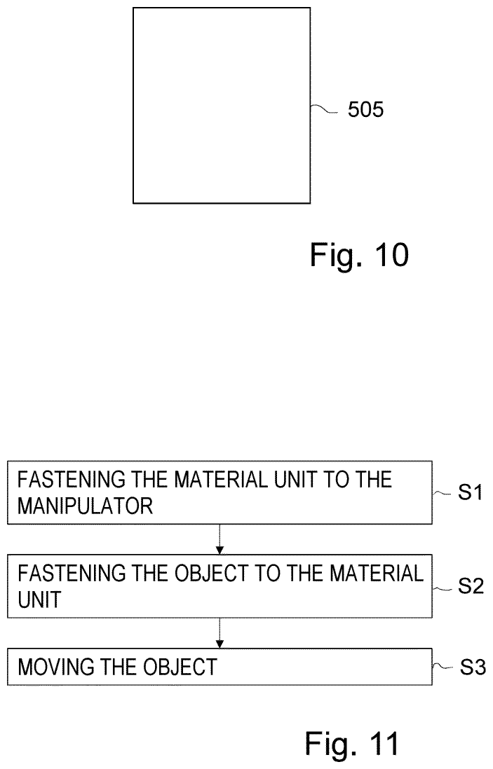

FIG. 10 shows one embodiment of the material unit 505. For example, the material unit 505 substantially has a cuboid shape. Longitudinal edges of the cuboid have for example an extent in the range between 5 μm and 50 μm. It is explicitly pointed out that the material unit 505 is not restricted to a cuboid shape and/or to the aforementioned range for the extent of the longitudinal edges. Rather, the material unit 505 may have any shape that is suitable for the invention. In the embodiment illustrated in FIG. 10 of the material unit 505, the material unit 505 is for example in the form of a conductive material unit and/or of a metal unit. In particular, it is provided that the material unit 505 is in the form of a material unit including copper and/or a material unit made of copper. It is explicitly pointed out that the invention is not restricted to copper as the metal. Rather, the metal unit may include any metal and/or be made from any metal that is suitable for the invention. The same also applies to alloys. It is also explicitly pointed out that the material unit 505 may be made of any material and/or include any material that is suitable for the invention. Further designs of the material unit 505 and exemplary methods for generating the material unit 505 are explained in more detail below.

The control unit 123 of the SEM according to FIG. 1 or 2, of the combination apparatus 200 according to FIG. 3 or 4, and/or of the particle beam apparatus 400 according to FIG. 5 or 6 includes the processor 127. Loaded in the processor 127 is a computer program product having program code which, upon execution, carries out a method for operating the SEM 100 according to FIG. 1 or 2, the combination apparatus 200 according to FIG. 3 or 4, and/or the particle beam apparatus 400 according to FIG. 5 or 6. Embodiments of the method according to the system described herein are explained below with regard to the combination apparatus 200 according to FIG. 3 or 4. The same applies with regard to the SEM 100 according to FIG. 1 or 2 and the particle beam apparatus 400 according to FIG. 5 or 6.

FIG. 11 shows one embodiment of the method according to the system described herein. The method serves to fasten the object 125 to the manipulator 501 in the combination apparatus 200 and to move the object 125 in the combination apparatus 200. The combination apparatus 200 is configured for example for analysis, observation and/or processing of the object 125.

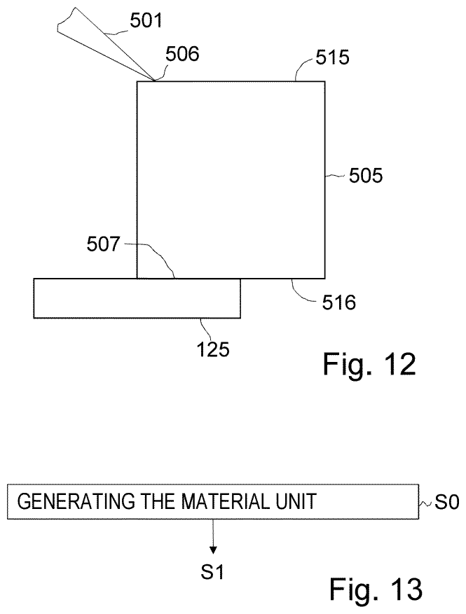

In method step S1, it is then provided that the material unit 505 is fastened to the manipulator 501 using the ion beam. For example, as illustrated in FIG. 12, the material unit 505 is fastened to the manipulator 501 in a first boundary region 506 between the material unit 505 and the manipulator 501 using the ion beam.

In particular, it is provided that the ion beam is guided onto the material unit 505 and over the material unit 505. For example, the ion beam is scanned over the surface of the material unit 505 using the first electrode arrangement 307 and the second electrode arrangement 308. In the process, material of the material unit 505 is ablated and reapplied in the first boundary region 506 between the material unit 505 and the manipulator 501, with the result that the material unit 505 is fastened to the manipulator 501. In addition or as an alternative, it is provided that the ion beam is guided onto the manipulator 501 and over the manipulator 501. For example, the ion beam is scanned over the surface of the manipulator 501. In the process, material of the manipulator 501 is ablated and reapplied in the first boundary region 506 between the manipulator 501 and the material unit 505, with the result that the material unit 505 is fastened to the manipulator 501.

In one embodiment of the method, it is additionally or alternatively provided that the material unit 505 is fastened to the manipulator 501 using a gas, which is provided by the gas feed device 1000. A precursor is let out of the precursor reservoir 1001 and conveyed to the material unit 505. As a result of interaction of the precursor with the ion beam, material of the material unit 505 is ablated and/or material is applied to the material unit 505 and/or the manipulator 501.

In another embodiment of the method, it is additionally or alternatively provided that the material unit 505 is fastened to the manipulator 501 likewise using a gas, which is provided by the gas feed device 1000. A precursor is let out of the precursor reservoir 1001 and conveyed to the manipulator 501. As a result of interaction of the precursor with the ion beam, material of the manipulator 501 is ablated and/or material is applied to the material unit 505 and/or the manipulator 501.

In method step S2, it is then provided that the object 125 is fastened to the material unit 505 using the ion beam. For example, as illustrated in FIG. 12, the object 125 is fastened to the material unit 505 in a second boundary region 507 between the object 125 and the material unit 505 using the ion beam.

In particular, it is provided that the ion beam is guided onto the material unit 505 and over the material unit 505. For example, the ion beam is scanned over the surface of the material unit 505 using the first electrode arrangement 307 and the second electrode arrangement 308. In the process, material of the material unit 505 is ablated and reapplied in the second boundary region 507 between the material unit 505 and the object 125, with the result that the object 125 is fastened to the material unit 505. In addition or as an alternative, it is provided that the ion beam is guided onto the object 125. For example, the ion beam is scanned over the surface of the object 125. In the process, material of the object 125 is ablated and reapplied in the second boundary region 507 between the object 125 and the material unit 505, with the result that the object 125 is fastened to the material unit 505.

In one embodiment of the method, it is additionally or alternatively provided that the object 125 is fastened to the material unit 505 using a gas, which is provided by the gas feed device 1000. A precursor is let out of the precursor reservoir 1001 and conveyed to the material unit 505. As a result of interaction of the precursor with the ion beam, material of the material unit 505 is ablated and/or material is applied to the material unit 505 and/or the object 125.

In another embodiment of the method, it is additionally or alternatively provided that the object 125 is fastened to the material unit 505 also using a gas, which is provided by the gas feed device 1000. A precursor is let out of the precursor reservoir 1001 and conveyed to the object 125. As a result of interaction of the precursor with the ion beam, material of the object 125 is ablated and/or material is applied to the material unit 505 and/or the object 125.

Accordingly, in the other embodiment it is provided that the material unit 505 is arranged between the manipulator 501 and the object 125. Expressed differently, the material unit 505 is arranged between the object 125 and the manipulator 501. However, the invention is not restricted to such an arrangement. Rather, it is also possible to select a different arrangement of the material unit 505 on the manipulator 501 and on the object 125 that is suitable for the invention.

In method step S3, it is provided that the object 125 fastened to the material unit 505 is moved using the manipulator 501 and/or the object stage 122. For example, when the object 125 is being moved, the object 125 can be removed from an object material. The object material is the material from which the object 125 that is to be analyzed, processed and/or imaged was prepared. The object 125 is prepared for example using the ion beam and includes in particular separating the object 125 from the object material. In this respect, it is provided for example that the object 125 is separated from the object material before the object 125 is moved using the manipulator 501 and/or the object stage 122. If the object 125 is moved exclusively using the manipulator 501, it is provided for example that the object 125 is completely separated from the object material.

FIG. 13 shows another embodiment of the method according to the system described herein. The method according to FIG. 13 is based on the method according to FIG. 11. Therefore, reference is made to the comments above, which also apply here. By contrast to the method according to FIG. 11, the method according to FIG. 13 includes a further method step S0, which is carried out before, during and/or after method step S1. In method step S0, the material unit 505 is generated.

In one embodiment of the method, it is provided that the material unit 505 is generated by processing a piece of material using the ion beam. For example, it is provided that the material unit 505 is cut out of the piece of material using the ion beam. The cutting out is effected in particular before the material unit 505 is fastened to the manipulator 501. To generate the material unit 505, for example, the ion beam is scanned over the surface of the piece of material. In the process, material of the piece of material is ablated in such a way that the material unit 505 is generated. The piece of material is in particular in the form of a conductive piece of material and/or a piece of material of metal. In particular, it is provided that the piece of material is in the form of a piece of material including copper and/or a piece of material made of copper. It is explicitly pointed out that the invention is not restricted to copper as the metal. Rather, the piece of material may include any metal and/or be made from any metal that is suitable for the invention. The same also applies to alloys. It is also pointed out that the invention is not restricted to the aforementioned embodiments for generating the material unit 505. Rather, the invention encompasses all methods that are suitable for generating the material unit 505. For example, the material unit 505 is generated outside the combination apparatus 200 using a laser device and/or at least one of the aforementioned methods. After the material unit 505 has been generated, the material unit 505 is fed into the combination apparatus 200.

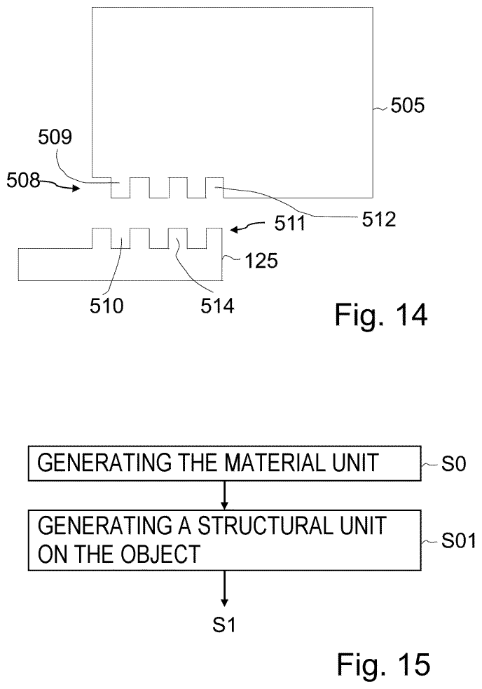

In an embodiment of the method according to FIG. 13, it is additionally or alternatively provided that, in method step S0, a first structural unit 508 is generated on the material unit 505 using the ion beam. FIG. 14 shows a schematic illustration of the material unit 505 and the object 125. When the object 125 is being fastened to the material unit 505, the generated first structural unit 508 is arranged on the object 125. For example, the first structural unit 508 has first projections 509, which are arranged in first cutouts 510 of a second structural unit 511 of the object 125. In addition, the first structural unit 508 has second cutouts 512, in which second projections 514 of the second structural unit 511 can be arranged.

FIG. 15 shows yet another embodiment of the method according to the system described herein. The method according to FIG. 15 is based on the method according to FIG. 13. Therefore, reference is made to the comments above, which also apply here. In particular, it is also provided in the case of the method according to FIG. 15 that the first structural unit 508 is generated on the material unit 505. By contrast to the method according to FIG. 13, the method according to FIG. 15 includes a further method step 501. In method step 501, it is provided that the second structural unit 511 is generated on the object 125 using the ion beam. The second structural unit 511 has for example the design described with regard to FIG. 14. Reference is made to the comments above, which also apply here. When the object 125 is being fastened to the material unit 505, the first structural unit 508 of the material unit 505 is arranged on the second structural unit 511 of the object 125.

As mentioned above, the aforementioned structural units 508, 511 may have any form. For example, the aforementioned structural units 508, 511 may have at least one aforementioned projection. In particular, it is provided that at least one of the aforementioned structural units 508, 511 has a comb-like form. Such a structural unit includes multiple tines (for example in the form of projections) and cutouts, each of which is arranged between two tines.

In one embodiment of the method according to the system described herein, the comments above regarding the structural unit or the multiple structural units apply additionally or alternatively also to the fastening of the material unit 505 to the manipulator 501. It is also possible to arranged at least one of the aforementioned structural units on the material unit 505 and/or on the manipulator 501 in order to connect the material unit 505 to the manipulator 501.

As illustrated in FIG. 12, it is additionally or alternatively provided that the material unit 505 has a first side 515, on which the material unit 505 is fastened to the manipulator 501. The material unit 505 also has a second side 516, on which the object 125 is fastened to the material unit 505. For example, the first side 515 and the second side 516 of the material unit 505 are aligned in relation to one another such that the material unit 505 is arranged between the manipulator 501 and the object 125. In particular, it is provided that the first side 515 and the second side 516 are situated opposite one another. It is explicitly pointed out that the invention is not restricted to the aforementioned alignment of the first side 515 and the second side 516. Rather, any alignment that is suitable for the invention can be used. For example, the first side 515 and the second side 516 may be aligned at an angle in relation to one another which is not 0° or 180°.

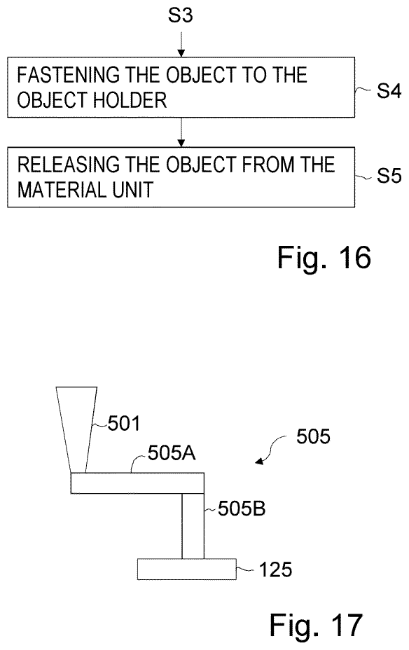

FIG. 16 shows yet another embodiment of the method according to the system described herein. The method according to FIG. 16 is based on the method according to FIG. 11. Therefore, reference is made to the comments above, which also apply here. By contrast to the method according to FIG. 11, the method according to FIG. 16 includes a further method step S4. In method step S4, it is additionally or alternatively provided that, after the object 125 has been moved, the object 125 is fastened to an object holder using the ion beam. For example, the object holder is in the form of a TEM object holder. However, the invention is not restricted to such object holders. Rather, any suitable object holder may be used.

To fasten the object 125 to the object holder, it is provided for example that the ion beam is guided onto the object 125 and over the object 125. For example, the ion beam is scanned over the surface of the object 125. In the process, material of the object 125 is ablated and reapplied in the boundary region between the object 125 and the object holder, with the result that the object 125 is fastened to the object holder. In addition or as an alternative, it is provided that the ion beam is guided onto the object holder and over the object holder. For example, the ion beam is scanned over the surface of the object holder. In the process, material of the object holder is ablated and reapplied in the boundary region between the object 125 and the object holder, with the result that the object 125 is fastened to the object holder.

In yet another embodiment, in method step S5 it is additionally or alternatively provided that, after the object 125 has been moved and in particular after the object 125 has been arranged on the object holder, the object 125 is released from the material unit 505. To release the object 125 from the material unit 505, it is provided for example that the ion beam is guided onto the object 125 and over the object 125. For example, the ion beam is scanned over the surface of the object 125. In the process, material is ablated in the boundary region between the object 125 and the material unit 505, with the result that the object 125 is released from the material unit 505. In addition or as an alternative, it is provided that a part of the material unit 505 is separated from the material unit 505 using the ion beam. However, the severed part of the material unit 505 remains fixedly connected to the object 125. The material unit 505, which is no longer connected to the object 125, can be reused, for example for the method according to the system described herein. In turn in addition or as an alternative, it is provided that a part of the object 125 is separated from the rest of the object 125 using the ion beam. However, the severed part of the object 125 remains fixedly connected to the material unit 505. The rest of the object 125 is fastened to the object holder and is imaged, analyzed and/or processed.

FIG. 17 shows one embodiment of a device according to the system described herein for fastening and/or moving the object 125. Basically, the device according to the system described herein is a system including the manipulator 501 and the material unit 505. For example, the device is generated according to FIG. 13 in method step S0. In the embodiment of FIG. 17, it is provided that the material unit 505 is generated using the ion beam in such a way that the material unit 505 includes a first material part 505A and a second material part 505B, the first material part 505A being arranged on the second material part 505B. Expressed differently, the material unit 505 has a multi-part form, with the material unit 505 including at least the first material part 505A and at least the second material part 505B. Accordingly, the material unit 505 may have more than two material parts. For example, the material unit 505 is generated in such a way that the first material part 505A is aligned in relation to the second material part 505B in such a way that the angle between the first material part 505A and the second material part 505B is not 0° or 180°. In particular, it is provided that the angle between the first material part 505A and the second material part 505B is 90° or substantially 90°. It is pointed out that the invention is not restricted to the aforementioned angles. Rather, any angle that is suitable for the invention can be used.

In another embodiment, the material unit 505 with the first material part 505A and the second material part 505B is generated outside the combination apparatus 200, for example using a laser device and/or using at least one of the aforementioned methods. After the material unit 505 has been generated, the material unit 505 is fed into the combination apparatus 200.

All the embodiments have the advantage that the object 125 can be properly connected to the manipulator 501 and an object holder (for example a TEM object holder) and be effectively connected in terms of time. An arrangement of the material unit 505 both on the manipulator 501 and on the object 125 makes it possible in particular to use material of the material unit 505 in order to fasten both the material unit 505 to the manipulator 501 and the object 125 to the material unit 505. By contrast to the prior art, the system described herein enables a good and secure connection both between the manipulator 501 and the material unit 505 and between the object 125 and the material unit 505, it only being possible to inadvertently release the connection again with difficulty. The system described herein also makes it possible to provide a connection both between the material unit 505 and the manipulator 501 and between the object 125 and the material unit 505 very quickly.

It is explicitly pointed out that the sequence of all the method steps of all the embodiments is not restricted to the sequence described above. Rather, the method steps can be carried out in any suitable sequence and/or in parallel.

The features of the invention that are disclosed in the present description, in the drawings and in the claims may be essential for the implementation of the invention in its various embodiments both individually and in any desired combinations. The invention is not restricted to the described embodiments. It can be varied within the scope of the claims and taking into account the knowledge of those skilled in the relevant art.

1. A method for fastening an object to a movable manipulator in a particle beam apparatus and for moving the object in the particle beam apparatus, the method comprising:
fastening a material unit configured to hold the object to a manipulator using a particle beam of the particle beam apparatus;
fastening the object to the material unit using the particle beam of the particle beam apparatus; and
using the manipulator and/or an object stage on which the object is arranged to move the object that is fastened to the material unit.

2. The method as claimed in claim 1, further comprising at least one of the following:
generating the material unit by processing a piece of material using the particle beam of the particle beam apparatus;
generating the material unit before the material unit is fastened to the manipulator using the particle beam of the particle beam apparatus.

3. The method as claimed in claim 1, further comprising at least one of the following:
cutting the material unit out of a piece of material using the particle beam of the particle beam apparatus;
cutting the material unit out of the piece of material before the material unit is fastened to the manipulator using the particle beam of the particle beam apparatus.

4. The method as claimed in claim 1, further comprising one of the following:
before the object is fastened to the material unit, generating a structural unit on the material unit using the particle beam of the particle beam apparatus and, when the object is being fastened to the material unit, arranging the structural unit on the object;
before the object is fastened to the material unit, generating a structural unit having at least one projection on the material unit using the particle beam of the particle beam apparatus and, when the object is being fastened to the material unit, arranging the structural unit on the object;
before the object is fastened to the material unit, generating a first structural unit on the material unit using the particle beam of the particle beam apparatus and, when the object is being fastened to the material unit, arranging the first structural unit of the material unit on a second structural unit of the object;
before the object is fastened to the material unit, generating a first structural unit having at least one first projection on the material unit using the particle beam of the particle beam apparatus and, when the object is being fastened to the material unit, arranging the first structural unit of the material unit on a second structural unit of the object, with the second structural unit including at least one first cutout;
before the object is fastened to the material unit, generating a first structural unit on the material unit using the particle beam of the particle beam apparatus, generating a second structural unit on the object using the particle beam of the particle beam apparatus, and when the object is being fastened to the material unit, arranging the first structural unit of the material unit on the second structural unit of the object;
before the object is fastened to the material unit, generating a first structural unit, which has at least one first projection, on the material unit using the particle beam of the particle beam apparatus, generating a second structural unit, which has at least one first cutout, on the object using the particle beam of the particle beam apparatus, and when the object is being fastened to the material unit, arranging the first projection of the first structural unit on the first cutout of the second structural unit.

5. The method as claimed in claim 1, further comprising at least one of the following:
fastening the material unit to the manipulator, by guiding the particle beam of the particle beam apparatus to the material unit in such a way that material of the material unit is applied both to the manipulator and to the material unit and between the manipulator and the material unit;
fastening the material unit to the manipulator, by guiding the particle beam of the particle beam apparatus to the manipulator in such a way that material of the manipulator is applied both to the material unit and to the manipulator and between the manipulator and the material unit;
fastening the object to the manipulator, by guiding the particle beam of the particle beam apparatus to the material unit in such a way that material of the material unit is applied both to the object and to the material unit and between the object and the material unit;
fastening the object to the material unit, by guiding the particle beam of the particle beam apparatus to the object in such a way that material of the object is applied both to the object and to the material unit and between the object and the material unit.

6. The method as claimed in claim 1, wherein the material unit has a first side, on which the material unit is fastened to the manipulator, and the material unit has a second side, on which the object is fastened to the material unit or the material unit has a first side, on which the material unit is fastened to the manipulator, and the material unit has a second side, on which the object is fastened to the material unit, with the first side and the second side being arranged opposite one another.

7. The method as claimed in claim 1, further comprising at least one of the following:
when the object is being moved using the manipulator and/or the object stage, removing the object from an object material;
before the object is moved using the manipulator and/or the object stage, separating the object from the object material;
when the object is being moved using the manipulator, moving the manipulator using a first movement device;
when the object is being moved using the object stage, moving the object stage using a second movement device.

8. The method as claimed in claim 1, further comprising at least one of the following:
after the object has been moved using the manipulator and/or the object stage, the object is fastened to an object holder using the particle beam of the particle beam apparatus;
after the object has been moved using the manipulator and/or the object holder, the object is released from the material unit using the particle beam of the particle beam apparatus.

9. The method as claimed in claim 1, wherein a metal unit is used as the material unit or a metal unit comprising copper is used as the material unit or a metal unit made of copper is used as the material unit.

10. The method as claimed in claim 1, wherein the material unit is fastened to the manipulator using a first gas, which is provided by a first gas feed device.

11. The method as claimed in claim 1, wherein the object is fastened to the material unit using a second gas, which is provided by a second gas feed device.

12. The method as claimed in claim 1, wherein the material unit is generated using the particle beam of the particle beam apparatus in such a way that the material unit comprises a first material part and a second material part, the first material part being arranged on the second material part.

13. A non-transitory computer readable medium containing program code which can be loaded into a processor and which, when executed, controls a particle beam apparatus to perform the following:
fastening a material unit configured to hold the object to a manipulator using a particle beam of the particle beam apparatus;
fastening the object to the material unit using the particle beam of the particle beam apparatus; and
using the manipulator and/or an object stage on which the object is arranged to move the object that is fastened to the material unit.

14. A particle beam apparatus for processing, observation and/or analysis of an object, comprising
at least one movable manipulator;
at least one material unit, which can be fastened to the manipulator;
at least one movable object stage for arranging the object;
at least one beam generator for generating a particle beam including charged particles;
at least one objective lens for focusing the particle beam onto the object, the manipulator and/or the material unit;
at least one scanning device for scanning the particle beam over the object, the manipulator and/or the material unit;
at least one detector unit for detecting interaction particles and/or interaction radiation which result/results from interaction of the particle beam with the object and/or with the manipulator and/or with the material unit; and
at least one processor coupled to a non-transitory computer readable medium that contains a program code which is loadable into the processor and which, when executed, fastens a material unit configured to hold the object the a manipulator using the particle beam of the particle beam apparatus, fastens the object to the material unit using the particle beam of the particle beam apparatus, and uses the manipulator and/or an object stage on which the object is arranged to move the object that is fastened to the material unit.

15. The particle beam apparatus as claimed in claim 14, wherein the particle beam apparatus has one of the following features:
the material unit has a structural unit, which can be arranged on the object;
the material unit has a structural unit with at least one projection, with the projection being able to be arranged on the object;
the material unit has a first structural unit, with the object having a second structural unit, and the first structural unit being able to be arranged on the second structural unit;
the material unit has a first structural unit with at least one first projection, with the object having a second structural unit with at least one first cutout and the first projection being able to be arranged on the first cutout;
the material unit has a first side for fastening to the manipulator and a second side for fastening the object.

16. The particle beam apparatus as claimed in claim 14, wherein the particle beam apparatus has at least one of the following features:
the material unit is in the form of a metal unit;
the material unit is in the form of a metal unit comprising copper;
the material unit is made of copper;
the material unit includes a first material part and a second material part, with the first material part being arranged on the second material part.

17. The particle beam apparatus as claimed in claim 14, wherein the particle beam apparatus has one of the following features:
a first gas feed device for feeding a first gas;
a second gas feed device for feeding a second gas.

18. The particle beam apparatus (200) as claimed in claim 14, further comprising:
at least one additional beam generator for generating an additional particle beam including additional charged particles; and
at least one additional objective lens for focusing the additional particle beam onto the object and/or onto the manipulator and/or the material unit.

19. The particle beam apparatus as claimed in claim 14, wherein the particle beam apparatus is an electron beam apparatus and/or an ion beam apparatus.

20. A device (501, 505) for fastening and moving an object in a particle beam device, comprising:
a movable manipulator, and
a material unit for fastening an object, with the material unit being fastened to the manipulator.

21. The device as claimed in claim 20, wherein the device has one of the following features:
the material unit has a structural unit, which can be arranged on the object;
the material unit has a structural unit with at least one projection, with the projection being able to be arranged on the object.

22. The device as claimed in claim 20, wherein the device has at least one of the following features:
the material unit is in the form of a metal unit;
the material unit is in the form of a metal unit including copper;
the material unit is made of copper;
the material unit includes a first material part and a second material part (505B), with the first material part being arranged on the second material part.
